(19) United States
(12) Patent Application Publication
(10) Pub. No.: US 2026/0239827 A1
(43) Pub. Date: Aug. 13, 2026

(54) MOTHER SUBSTRATE MANUFACTURING METHOD AND MOTHER SUBSTRATE FOR DISPLAY DEVICE

(71) Applicant: Magnolia White Corporation, Tokyo (JP)

(72) Inventors: Sho YANAGISAWA, Tokyo (JP); Kota MAKISHI, Tokyo (JP)

(73) Assignee: Magnolia White Corporation, Tokyo (JP)

(21) Appl. No.: 19/533,325

(22) Filed: Feb. 9, 2026

(30) Foreign Application Priority Data
Feb. 10, 2025 (JP) 2025-019876

(51) Int. Cl. H10K 59/122; H10K 59/12; H10K 59/35; H10K 59/80

(52) U.S. Cl. CPC H10K 59/122; H10K 59/1201; H10K 59/873; H10K 59/352

(57) ABSTRACT

According to one embodiment, a manufacturing method of a mother substrate includes forming a lower electrode in a display area, forming a rib layer covering a panel portion and a margin area, forming, in the display area, a first partition including a lower portion and an upper portion, forming, in the margin area, a second partition including the lower portion and the upper portion, forming, in the panel portion and the margin area, a first stacked film and a first sealing layer, and etching for removing, among the first stacked film and the first sealing layer formed in the panel portion and the margin area, the first stacked film and the first sealing layer that are formed outside a target area in which an organic layer of a first color is provided.

### CROSS-REFERENCE TO RELATED APPLICATION

This application is based upon and claims the benefit of priority from Japanese Patent Application No. 2025-019876, filed Feb. 10, 2025, the entire contents of which are incorporated herein by reference.

### FIELD

Embodiments described herein relate generally to a mother substrate manufacturing method and a mother substrate for a display device.

### BACKGROUND

Recently, display devices with organic light-emitting diodes (OLED) applied thereto as display elements have been put into practical use. In the manufacturing of such display devices, an inspection is implemented to confirm whether the elements on the substrate are formed as designed. A technique for efficiently and accurately implementing this inspection has been required.

### BRIEF DESCRIPTION OF THE DRAWINGS

FIG. 1 is a view showing a configuration example of a display device according to one embodiment.

FIG. 2 is a schematic plan view showing an example of the layout of subpixels.

FIG. 3 is a schematic cross-sectional view of a display panel along the III-III line of FIG. 2.

FIG. 4 is a schematic plan view of a mother substrate according to one embodiment.

FIG. 5 is a schematic plan view of a part of the mother substrate according to one embodiment.

FIG. 6 is a schematic plan view showing an example of the configuration applicable to a test pattern according to one embodiment.

FIG. 7 is a schematic cross-sectional view of the mother substrate along the VII-VII line of FIG. 6.

FIG. 8A is a schematic plan view showing an example of the configuration applicable to a test pattern according to one embodiment.

FIG. 8B is a schematic plan view showing an example of the configuration applicable to a test pattern according to one embodiment.

FIG. 9 is a schematic plan view showing an example of the configuration applicable to a test pattern according to one embodiment.

FIG. 10 is a schematic cross-sectional view of the mother substrate along the X-X line of FIG. 9.

FIG. 11 is a schematic plan view showing an example of the configuration applicable to a test pattern according to one embodiment.

FIG. 12 is a schematic plan view showing an example of the configuration applicable to a test pattern according to one embodiment.

FIG. 13 is a schematic cross-sectional view of the mother substrate along the XIII−XIII line of FIG. 12.

FIG. 14 is a schematic plan view showing an example of the configuration applicable to a test pattern according to one embodiment.

FIG. 15 is a schematic plan view showing an example of the configuration applicable to a test pattern according to one embodiment.

FIG. 16 is a schematic cross-sectional view of the mother substrate along the XVI-XVI line of FIG. 15.

FIG. 17 is a schematic plan view showing an example of the configuration applicable to a test pattern according to one embodiment.

FIG. 18 is a flowchart showing an example of the manufacturing method of the display device according to one embodiment.

FIG. 19A is a schematic cross-sectional view showing a process of forming a panel portion in the mother substrate according to one embodiment.

FIG. 19B is a schematic cross-sectional view showing a process following the process shown in FIG. 19A.

FIG. 19C is a schematic cross-sectional view showing a process following the process shown in FIG. 19B.

FIG. 19D is a schematic cross-sectional view showing a process following the process shown in FIG. 19C.

FIG. 19E is a schematic cross-sectional view showing a process following the process shown in FIG. 19D.

FIG. 19F is a schematic cross-sectional view showing a process following the process shown in FIG. 19E.

FIG. 19G is a schematic cross-sectional view showing a process following the process shown in FIG. 19F.

FIG. 19H is a schematic cross-sectional view showing a process following the process shown in FIG. 19G.

FIG. 19I is a schematic cross-sectional view showing a process following the process shown in FIG. 19H.

FIG. 19J is a schematic cross-sectional view showing a process following the one shown in FIG. 19I.

FIG. 20A is a schematic cross-sectional view showing a removal process of a rib layer in a terminal portion.

FIG. 20B is a schematic cross-sectional view showing a process following the process shown in FIG. 20A.

FIG. 21A is a schematic cross-sectional view showing processes of forming elements constituting display elements in a test pattern according to one embodiment.

FIG. 21B is a schematic cross-sectional view showing a process following the process shown in FIG. 21A.

FIG. 21C is a schematic cross-sectional view showing a process following the process shown in FIG. 21B.

FIG. 21D is a schematic cross-sectional view showing a process following the process shown in FIG. 21C.

FIG. 22A is a schematic cross-sectional view showing an example of measurement processes of one embodiment.

FIG. 22B is a schematic cross-sectional view showing an example of measurement processes of one embodiment.

FIG. 22C is a schematic cross-sectional view showing an example of measurement processes of one embodiment.

FIG. 22D is a schematic cross-sectional view showing an example of measurement processes of one embodiment.

### DETAILED DESCRIPTION

In general, according to one embodiment, a manufacturing method of a mother substrate includes preparing a substrate including a plurality of panel portions each having a display area and a surrounding area around the display area, and a margin area around the panel portion, forming a lower electrode in the display area, forming a rib layer covering the panel portion and the margin area, forming, in the display area, a first partition including a lower portion and an upper portion having an end portion protruding relative to a side surface of the lower portion, forming, in the margin area, a second partition including the lower portion and the upper portion, forming, in the panel portion and the margin area, a first stacked film at least including an organic layer of a first color and a first sealing layer covering the first stacked film, and etching for removing, among the first stacked film and the first sealing layer formed in the panel portion and the margin area, the first stacked film and the first sealing layer that are formed outside a target area in which the organic layer of the first color is provided. The etching does not remove parts that are formed on the second partition or on a side surface of the second partition of the first stacked film and the first sealing layer in the target area in the margin area.

According to another embodiment, a mother substrate for a display device includes a plurality of panel portions each including a display area and a surrounding area around the display area, a margin area around the plurality of panel portions, a lower electrode provided in the display area, a rib layer provided in the plurality of panel portions and the margin area, a first partition provided in the display area, a first stacked film provided in a first area included in each of the plurality of panel portions and the margin area and including an organic layer of a first color, a first sealing layer covering the first stacked film, and a second stacked film provided in a second area included in each of the plurality of panel portions and the margin area and including an organic layer of a second color, a second sealing layer covering the second stacked film, and a plurality of second partitions provided in the first area and the second area included in the margin area. Each of the first partition and the second partition has a lower portion and an upper portion having an end portion protruding relative to a side surface of the lower portion. The first stacked film is provided on the upper portion of the second partition provided in the first area. The second sealing layer adhering to the second partition is provided around the second partition provided in the second area. The second stacked film is provided on the upper portion of the second partition provided in the second area. The second sealing layer adhering to the second partition is provided around the second partition provided in the second area.

According to another embodiment, a mother substrate for a display device includes a plurality of panel portions each including a display area and a surrounding area around the display area, a margin area around the plurality of panel portions, a lower electrode provided in the display area, a rib layer provided in the plurality of panel portions and the margin area, a first partition provided in the display area, a first stacked film provided in a first area included in each of the plurality of panel portions and the margin area and including an organic layer of a first color, a first sealing layer covering the first stacked film, and a second stacked film provided in a second area included in each of the plurality of panel portions and the margin area and including an organic layer of a second color, a second sealing layer covering the second stacked film, and a plurality of second partitions provided at positions overlapping the first area and the second area included in the margin area in plan view. Each of the first partition and the second partition has a lower portion and an upper portion having an end portion protruding relative to a side surface of the lower portion. The second partition has an aperture at a center of the second partition. The first stacked film is provided in an aperture of the second partition provided at a position overlapping the first area. The first sealing layer adhering to the second partition is provided around the aperture of the second partition provided at the position overlapping the first area. The second stacked film is provided in an aperture of the second partition provided at a position overlapping the second area. The second sealing layer adhering to the second partition is provided around the aperture of the second partition provided at the position overlapping the second area.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc. of the respective parts are schematically illustrated in the drawings, compared to the actual modes. However, the schematic illustration is merely an example, and adds no restrictions to the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as an X-direction. A direction parallel to the Y-axis is referred to as a Y-direction. A direction parallel to the Z-axis is referred to as a Z-direction. The Z direction is the normal direction of a plane including the X direction and the Y direction. When various elements are viewed parallel to the Z direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

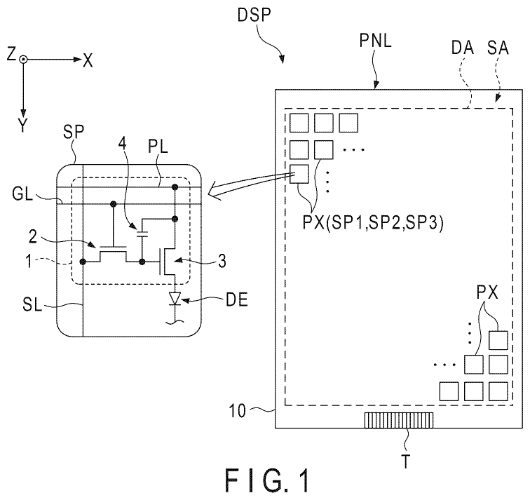

FIG. 1 is a view showing a configuration example of a display device DSP according to an embodiment. The display device DSP comprises a display panel PNL including an insulating substrate 10. The display panel PNL has a display area DA for displaying images and a surrounding area SA around the display area DA. The substrate 10 may be glass or a resinous film having flexibility.

In the present embodiment, the substrate 10 has a rectangular shape as seen in plan view. The shape of the substrate 10 in plan view is not limited to a rectangle and may be another shape such as a square, a circle or an elliptic shape.

The display area DA comprises a plurality of pixels PX arranged in a matrix in the X direction and the Y direction. Each pixel PX includes a plurality of subpixels SP displaying different colors. The present embodiment assumes a case where each pixel PX includes a blue subpixel SP1, a green subpixel SP2, and a red subpixel SP3. However, each pixel PX may include a subpixel SP which exhibits another color such as white in addition to the subpixels SP1, SP2, and SP3 or instead of one of the subpixels SP1, SP2, and SP3.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A plurality of scanning lines GL supplying a scanning signal to the pixel circuit 1 of each subpixel SP, a plurality of signal lines SL supplying a video signal to the pixel circuit 1 of each subpixel SP, and a plurality of power lines PL are provided in the display area DA. In the example of FIG. 1, the scanning lines GL and the power lines PL extend in the X direction, and the signal lines SL extend in the Y direction.

A gate electrode of the pixel switch 2 is connected to the scanning line GL. One of a source electrode and a drain electrode of the pixel switch 2 is connected to the signal line SL. The other is connected to a gate electrode of the drive transistor 3 and the capacitor 4. In the drive transistor 3, one of a source electrode and a drain electrode is connected to the power line PL and the capacitor 4. The other is connected to the display element DE.

The configuration of the pixel circuit 1 is not limited to the shown example. For example, the pixel circuit 1 may comprise more thin-film transistors and capacitors.

The display device DSP further comprises a terminal portion T provided in the surrounding area SA. For example, a flexible printed circuit board is connected to the terminal portion T. Signals and voltages for driving the pixel circuit 1 are input to the display device DSP through this flexible circuit board and the terminal portion T.

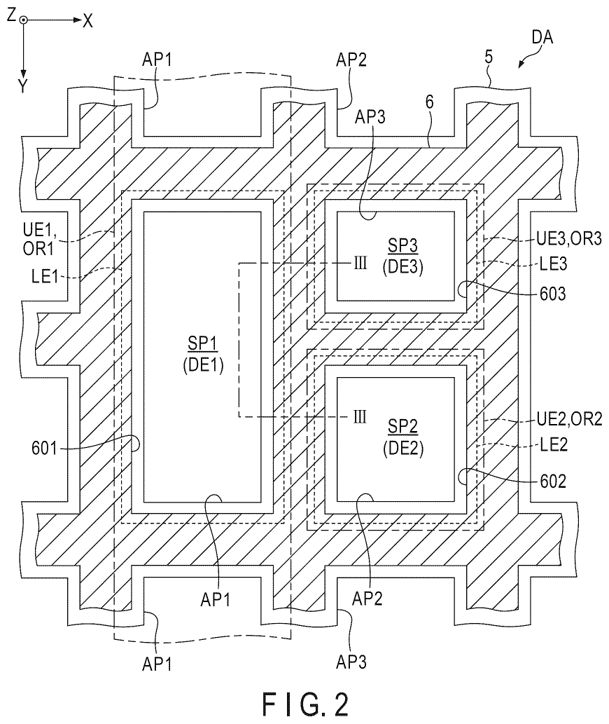

FIG. 2 is a schematic plan view showing an example of the layout of the subpixels SP1, SP2, and SP3. In the example of FIG. 2, the subpixels SP2 and SP3 are arranged with the subpixel SP1 in the X-direction. Further, the subpixels SP2 and SP3 are arranged in the Y direction.

When the subpixels SP1, SP2 and SP3 are arranged in this layout, in the display area DA, a row in which the subpixels SP2 and SP3 are alternately arranged in the Y direction and a row in which the plurality of subpixels SP1 are repeatedly arranged in the Y direction are formed. These columns are alternately arranged in the X-direction. The layout of the subpixels SP1, SP2, and SP3 is not limited to the example of FIG. 2.

A rib layer 5 is provided in the display area DA. The rib layer 5 has pixel apertures AP1, AP2, and AP3 in the respective subpixels SP1, SP2, and SP3. In the example of FIG. 2, the pixel aperture AP1 is greater than the pixel aperture AP2, and the pixel aperture AP2 is greater than the pixel aperture AP3. Thus, among the subpixels SP1, SP2, and SP3, the aperture ratio of the subpixel SP1 is the greatest, and the aperture ratio of the subpixel SP3 is the least.

The subpixel SP1 comprises a lower electrode LE1, an upper electrode UE1, and an organic layer OR1, which overlap the pixel aperture AP1. The subpixel SP2 comprises a lower electrode LE2, an upper electrode UE2, and an organic layer OR2, which overlap the pixel aperture AP2. The subpixel SP3 comprises a lower electrode LE3, an upper electrode UE3, and an organic layer OR3 that overlap the pixel aperture AP3.

Parts overlapping the pixel aperture AP1 of the lower electrode LE1, the upper electrode UE1, and the organic layer OR1 constitute a display element DE1 of the subpixel SP1. Parts overlapping the pixel aperture AP2 of the lower electrode LE2, the upper electrode UE2, and the organic layer OR2 constitute a display element DE2 of the subpixel SP2. Parts overlapping the pixel aperture AP3 of the lower electrode LE3, the upper electrode UE3, and the organic layer OR3 constitute a display element DE3 of the subpixel SP3. Each of the display elements DE1, DE2, and DE3 may further include a cap layer to be described later. The rib layer 5 surrounds each of the display elements DE1, DE2, and DE3.

A conductive partition 6 (the first partition) is provided above the rib layer 5. The partition 6 functions as lines applying common voltage to the upper electrodes UE1, UE2, and UE3. The partition 6 entirely overlaps the rib layer 5 and has the same planar shape as the rib layer 5.

More specifically, the partition 6 has a partition aperture 601 in the subpixel SP1, a partition aperture 602 in the subpixel SP2, and a partition aperture 603 in the subpixel SP3. The partition apertures 601, 602, and 603 are greater than the respective pixel apertures AP1, AP2, and AP3. The partition apertures 601, 602, and 603 overlap the whole of the respective display elements DE1, DE2, and DE3. That is, the partition 6 surrounds the display elements DE1, DE2, and DE3.

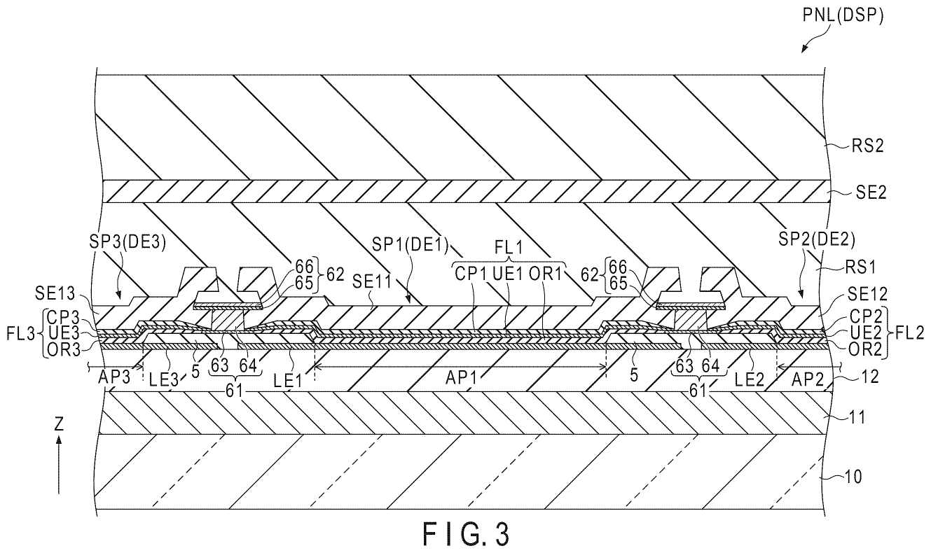

FIG. 3 is a schematic cross-sectional view of the display panel PNL along the III-III line of FIG. 2. A circuit layer 11 (a conductive layer) is provided on the substrate 10 described above. The circuit layer 11 includes various circuits and lines such as the pixel circuit 1, the scanning lines GL, the signal lines SL, and the power lines PL shown in FIG. 1. The circuit layer 11 is covered with an organic insulating layer 12. The organic insulating layer 12 functions as a planarization film which planarizes irregularities formed by the circuit layer 11.

The lower electrodes LE1, LE2, and LE3 are provided on the organic insulating layer 12. The rib layer 5 is provided on the organic insulating layer 12 and the lower electrodes LE1, LE2, and LE3. End portions of the lower electrodes LE1, LE2, and LE3 are covered with the rib layer 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6 includes a conductive lower portion 61 provided on the rib layer 5 and an upper portion 62 provided on the lower portion 61. The upper portion 62 has the width greater than the width of the lower portion 61. This configuration allows the both end portions of the upper portion 62 to protrude relative to the side surfaces of the lower portion 61. This shape of the partition 6 is called an overhang shape.

In the example of FIG. 3, the lower portion 61 has a bottom layer 63 provided on the rib layer 5, and a stem layer 64 provided on the bottom layer 63. For example, the bottom layer 63 is formed to be thinner than the stem layer 64. In the example of FIG. 3, the both end portions of the bottom layer 63 protrude relative to the side surfaces of the stem layer 64.

Further, in the example of FIG. 3, the upper portion 62 comprises a first top layer 65 and a second top layer 66 provided on the first top layer 65. For example, the width of the second top layer 66 is slightly smaller than the width of the first top layer 65. The configuration is not limited to this, and the first top layer 65 and the second top layer 66 may have the same width.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 contact the lower portion 61 of the partition 6.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers which improve the extraction efficiency of the light emitted from the organic layers OR1, OR2, and OR3, respectively.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

Sealing layers SE11, SE12 and SE13 are provided in the subpixels SP1, SP2 and SP3, respectively. The sealing layer SE11 continuously covers the stacked film FL1 and the subpixel SP1 and the partition 6 around them. The sealing layer SE12 continuously covers the stacked film FL2 and the subpixel SP2 and the partition 6 around them. The sealing layer SE13 continuously covers the stacked film FL3 and the subpixel SP3 and the partition 6 around them.

In the example of FIG. 3, the sealing layer SE11 located on the partition 6 between the subpixels SP1 and SP2 is spaced apart from the sealing layer SE12 located on this partition 6. The sealing layer SE11 located on the partition 6 between the subpixels SP1 and SP3 is spaced apart from the sealing layer SE13 located on this partition 6. In another example, an end portion of the sealing layer SE11 and an end portion of the sealing layer SE12 may overlap on the partition 6. Similarly, an end portion of the sealing layer SE11 and an end portion of the sealing layer SE13 may overlap on the partition 6.

The sealing layers SE11, SE12, and SE13 are covered with a resin layer RS1. The resin layer RS1 is covered with the sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a touch panel, a protective film, or a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as a polyimide. Each of the rib layer 5 and the sealing layers SE11, SE12, SE13, and SE2 is formed of an inorganic insulating material such as a silicon nitride (SiNx), a silicon oxide (SiOx), or a silicon oxynitride (SiON). In one example, the rib layer 5 is formed of a silicon oxynitride, and each of the sealing layers SE11, SE12, SE13, and SE2 is formed of a silicon nitride. Each of the resin layers RS1 and RS2 is formed of, for example, a resinous material (an organic insulating material) such as epoxy resin or acrylic resin.

Each of the lower electrodes LE1, LE2, and LE3 has a reflective layer formed of, for example, silver, and a pair of conductive oxide layers covering the upper and lower surfaces of the reflective layer. Each of the conductive oxide layers can be formed of, for example, a transparent conductive oxide such as an indium tin oxide (ITO), an indium zinc oxide (IZO), or an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is formed of a plurality of thin films including a light emitting layer. For example, each of the organic layers OR1, OR2, and OR3 has a structure in which a hole injection layer, a hole transport layer, an electron blocking layer, a light emitting layer, a hole blocking layer, an electron transport layer, and an electron injection layer are stacked in this order in the Z-direction. The organic layers OR1, OR2, and OR3 each may comprise other structures such as a tandem structure including a plurality of light emitting layers.

Each of the cap layers CP1, CP2, and CP3 comprises, for example, a multilayer structure in which a plurality of transparent layers are stacked. These transparent layers may include a layer formed of an inorganic material and a layer formed of an organic material. The transparent layers have refractive indexes different from each other. For example, the refractive indexes of these transparent layers are different from the refractive indexes of the upper electrodes UE1, UE2, and UE3 and the refractive indexes of the sealing layers SE11, SE12, and SE13. At least one of the cap layers CP1, CP2, and CP3 may be omitted.

For example, each of the bottom layer 63 and the stem layer 64 of the lower portion 61 of the partition 6 is formed of a metal material. For the metal material of the bottom layer 63, for example, molybdenum, titanium, a titanium nitride (TiN), a molybdenum-tungsten alloy (MoW), or a molybdenum-niobium alloy (MoNb) can be used. For the metal material of the stem layer 64, for example, aluminum, an aluminum-neodymium alloy (AlNd), an aluminum-yttrium alloy (AlY), or an aluminum-silicon alloy (AlSi) can be used. The stem layer 64 may be formed of an insulating material. Further, the lower portion 61 may be formed of a single layer.

For example, the first top layer 65 of the partition 6 is formed of a metal material. Further, the second top layer 66 of the partition 6 is formed, for example, of a conductive oxide material. For the metal material forming the first top layer 65, for example, titanium, a titanium nitride, molybdenum, tungsten, a molybdenum-tungsten alloy, or a molybdenum-niobium alloy may be used. For a conductive oxide forming the second top layer 66, for example, an ITO or an IZO may be used. The upper portion 62 may comprise three or more layers. Alternatively, the upper portion 62 may be formed of a single layer. The upper portion 62 may further include a layer formed of an insulating material.

Common voltage is applied to the partition 6. This common voltage is applied to each of the upper electrodes UE1, UE2, and UE3 contacting the lower portions 61. Pixel voltages according to the video signals of the signal lines SL are applied to the lower electrodes LE1, LE2, and LE3 through the respective pixel circuits 1 provided in the subpixels SP1, SP2, and SP3.

The organic layers OR1, OR2, and OR3 emit light in response to the application of a voltage. More specifically, when a potential difference is formed between the lower electrode LE1 and the upper electrode UE1, the light emitting layer of the organic layer OR1 emits light in the blue wavelength range. When a potential difference is formed between the lower electrode LE2 and the upper electrode UE2, the light emitting layer of the organic layer OR2 emits light in the green wavelength range. When a potential difference is formed between the lower electrode LE3 and the upper electrode UE3, the light emitting layer of the organic layer OR3 emits light in the red wavelength range.

In another example, the light emitting layers of the organic layers OR1, OR2, and OR3 may emit light of the same color (for example, white). In this case, the display device DSP may comprise a color filter that converts light emitted from the light emitting layers into light of the colors corresponding to those of the subpixels SP1, SP2, and SP3. In addition, the display device DSP may comprise a layer including quantum dots that are excited by light emitted from the light emitting layers to generate the light of the colors corresponding to those of the subpixels SP1, SP2, and SP3.

In the manufacturing of the display device DSP, a large mother substrate is fabricated, the mother substrate comprising a plurality of areas (panel portions) each corresponding to the display panel PNL. The following will describe a configuration applicable to this mother substrate.

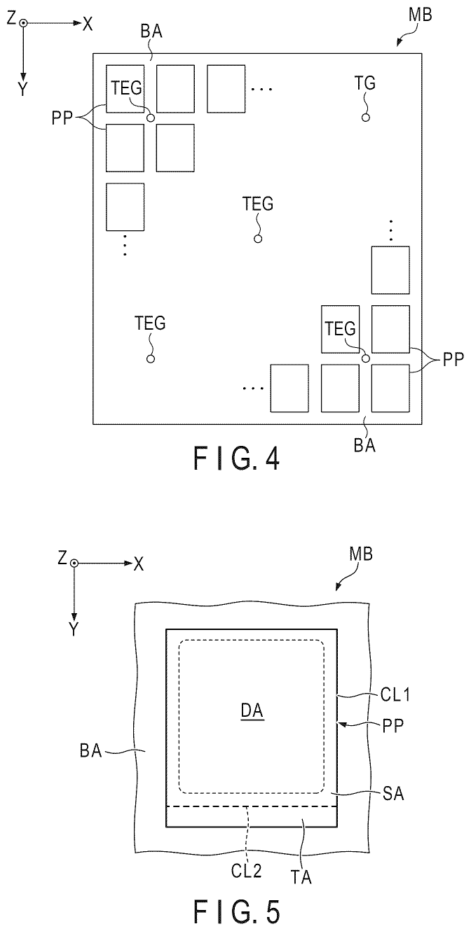

FIG. 4 is a schematic plan view of a mother substrate MB (a mother substrate for a display device) according to the present embodiment. For example, the mother substrate MB has a rectangular shape as shown in the figure. However, the mother substrate MB may have another shape such as a circular shape.

The mother substrate MB comprises a plurality of panel portions PP provided in a matrix and a margin area BA around these panel portions PP. In the example of FIG. 4, the panel portions PP are arranged in the X-direction and the Y-direction via the margin area BA. However, at least two of the panel portions PP provided in the mother substrate MB may be adjacent to each other without intervention of the margin area BA.

The mother substrate MB further comprises at least one test pattern TEG. In the example of FIG. 4, a plurality of test patterns TEG are provided in the margin area BA. Positions and number of these test patterns TEG are not particularly limited. In one example, the test patterns TEG are preferably distributed at various positions such as in the vicinity of the end portion of the mother substrate MB and near a center of the mother substrate MB.

FIG. 5 is a schematic plan view of a part of the mother substrate MB. This figure focuses attention on one panel portion PP. The outer shape of the panel portion PP corresponds to a cut line CL1 for cutting out the panel portion PP from the mother substrate MB.

Each panel portion PP has the display area DA and the surrounding area SA. Further, the surrounding area SA includes an inspection area TA. In the inspection area TA, an inspection pad for inspecting the operation of the display panel PNL and the like are provided.

In each panel portion PP, a cut line CL2 is formed. This cut line CL2 divides the panel portions PP into a part including the display area DA and a part including the inspection area TA.

In the manufacturing of the display device DSP, the panel portion PP is first cut out from the mother substrate MB along the cut line CL1. Further, this cut-out panel portion PP undergoes the inspection using the inspection pad. After this inspection, the inspection area TA is cut out from the panel portion PP along the cut line CL2.

The test pattern TEG shown in FIG. 4 is provided in the surrounding area SA as well as the margin area BA. For example, the test pattern TEG can be provided in the inspection area TA. In this case, the test pattern TEG does not remain in the panel portion PP in which the inspection area TA has been cut out along the cut line CL2. Even when the test pattern TEG is provided in the margin area BA as shown in FIG. 4, the test pattern TEG does not remain in the panel portion PP after the inspection area TA is separated along the cut line CL2.

In another example, the test pattern TEG may be provided in a part excluding the inspection area TA of the surrounding area SA. In this case, the test pattern TEG remains in the panel portion PP in which the inspection area TA has been cut out along the cut line CL2.

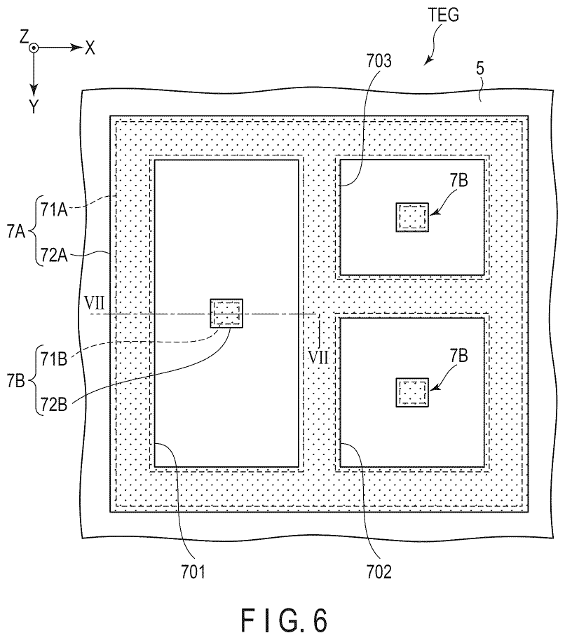

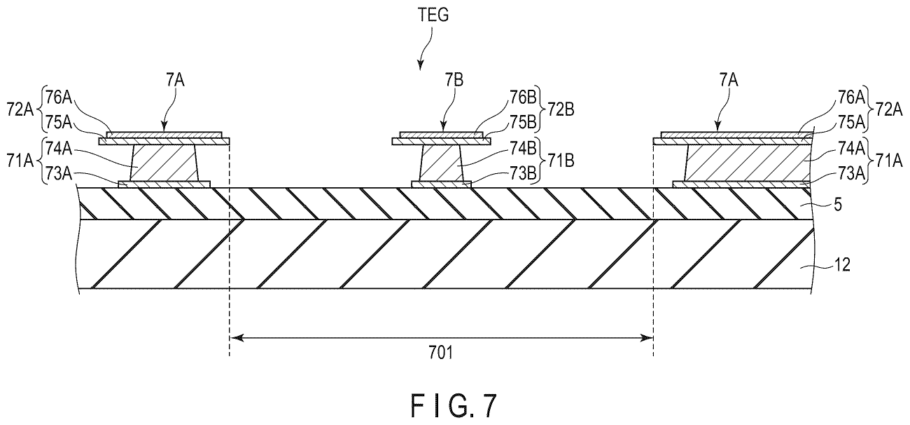

FIG. 6 is a schematic plan view showing an example of a configuration applicable to the test pattern TEG. FIG. 7 is a schematic cross-sectional view of the mother substrate MB including the test pattern TEG along the VII-VII line of FIG. 6. FIG. 7 omits the illustration of elements below the organic insulating layer 12. The configuration shown in FIG. 6 and FIG. 7 is applicable, for example, to the test pattern TEG for checking misalignment between the partition 6 and elements constituting the display element DE.

As shown in FIG. 6, the test pattern TEG is constituted by the rib layer 5 and a partition 7A (the third partition) and a plurality of partitions 7B (the second partitions and the protrusion portions).

The rib layer 5 is provided across the panel portions PP and the margin area BA shown in FIG. 4.

The partition 7A is provided in the margin area BA. In the same manner as the partition 6, the partition 7A extends in the X-direction and the Y-direction and is formed in a lattice shape. In the example of FIG. 6, the partition 7A has partition apertures 701, 702, and 703. For example, the outer shapes and the layout of the partition apertures 701, 702, and 703 are the same as those of the partition apertures 601, 602, and 603 shown in FIG. 2. That is, the partition aperture 701 is a partition aperture corresponding to the subpixel SP1, the partition aperture 702 is a partition aperture corresponding to the subpixel SP2, and the partition aperture 703 is a partition aperture corresponding to the subpixel SP3.

The partition 7B (described later) surrounded by the partition aperture 701 and the area overlapping the partition aperture 701 in plan view are the areas (a target area, the first area) in which elements constituting the display element DE1 are provided. The partition 7B (described later) surrounded by the partition aperture 702 and the area overlapping the partition aperture 702 in plan view are the areas (the target area, the second area) in which elements constituting the display element DE2 are provided. The partition 7B (described later) surrounded by the partition aperture 703 and the area overlapping the partition aperture 703 in plan view are the areas (the target area) in which elements constituting the display element DE3 are provided.

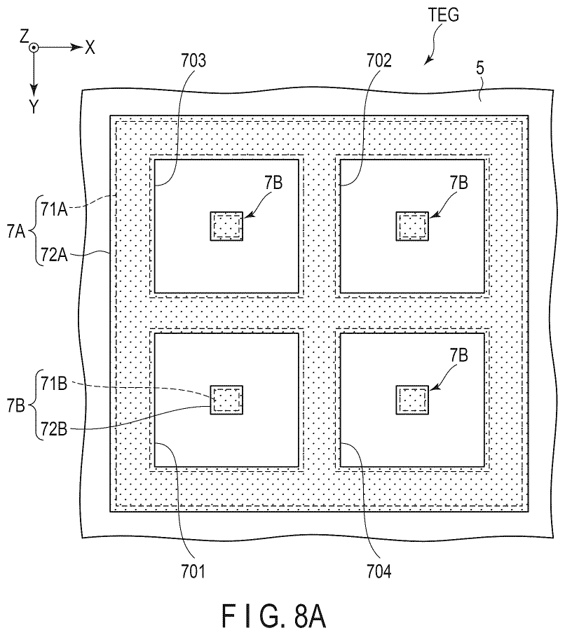

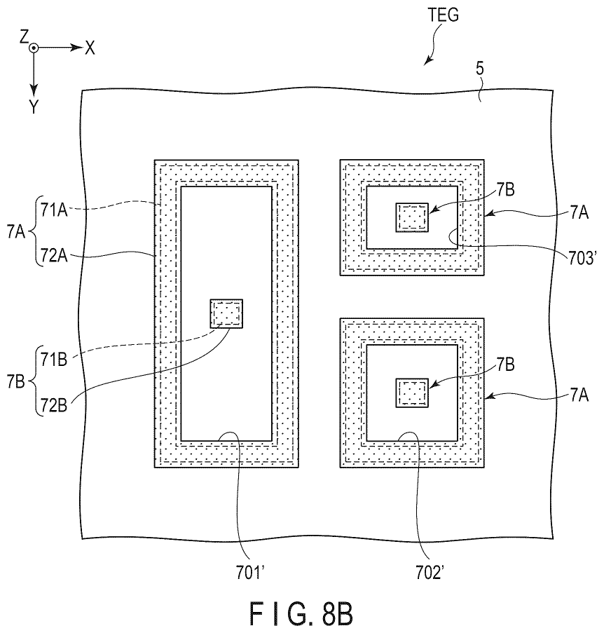

The figures show the case where the outer shapes and the layout of the partition apertures 701, 702, and 703 are the same as those of the partition apertures 601, 602, and 603 shown in FIG. 2. For example, as shown in FIG. 8A, the partition 7A may have one or more partition apertures having an outer shape different from the partition apertures 601, 602, and 603. In FIG. 8A, the partition 7A further has a partition aperture 704 corresponding to another color subpixel SP such as a white subpixel in addition to the partition apertures 701, 702, and 703 corresponding to the respective subpixels SP1, SP2, and SP3, and the outer shapes of the partition apertures 701, 702, 703, and 704 are square in this example.

As shown in FIG. 8B, the plurality of partitions 7A may be provided, outer shapes and layouts of the partition apertures of the partitions 7A may be the same as those of the partition apertures 601, 602, and 603 shown in FIG. 2, and the partitions 7A may have respective partition apertures 701', 702', and 703'.

In the example of FIG. 6, the plurality of partitions 7B are each provided at the center of the respective partition apertures 701, 702, and 703 and are surrounded by the partition apertures 701, 702, and 703. The figure shows a case where each side length of the partition 7B is smaller than the width of the partition 7A. Each side length of the partition 7B may be approximately equivalent to the width of the partition 7A.

As shown in FIG. 6 and FIG. 7, the partitions 7A and 7B each include lower portions 71A and 71B (bottom layers 73A and 73B and stem layers 74A and 74B) and the upper portions 72A and 72B (first top layers 75A and 75B and second top layers 76A and 76B), in the same manner as the partition 6. Further, in the same manner as the partition 6, the partitions 7A and 7B are configured such that both end portions of the bottom layers 73A and 73B protrude relative to side surfaces of the stem layer 74A and 74B.

The lower portions 71A and 71B of the partitions 7A and 7B are formed of the same material as the lower portion 61 of the partition 6. More specifically, the bottom layers 73A and 73B and the stem layers 74A and 74B are respectively formed of the same materials as the bottom layer 63 and the stem layer 64 of the partition 6. The thicknesses of the bottom layers 73A and 73B are equivalent to the thickness of the bottom layer 63 of the partition 6. Further, the thicknesses of the stem layers 74A and 74B are equivalent to the thickness of the stem layer 64 of the partition 6.

The upper portions 72A and 72B of the partitions 7A and 7B are formed of the same materials as the upper portion 62 of the partition 6. More specifically, the first top layers 75A and 75B and the second top layers 76A and 76B are respectively formed of the same materials as the first top layer 65 and the second top layer 66 of the partition 6. The thicknesses of the first top layers 75A and 75B are equivalent to the thickness of the first top layer 65 of the partition 6. The thicknesses of the second top layers 76A and 76B are equivalent to the thickness of the second top layer 66 of the partition 6.

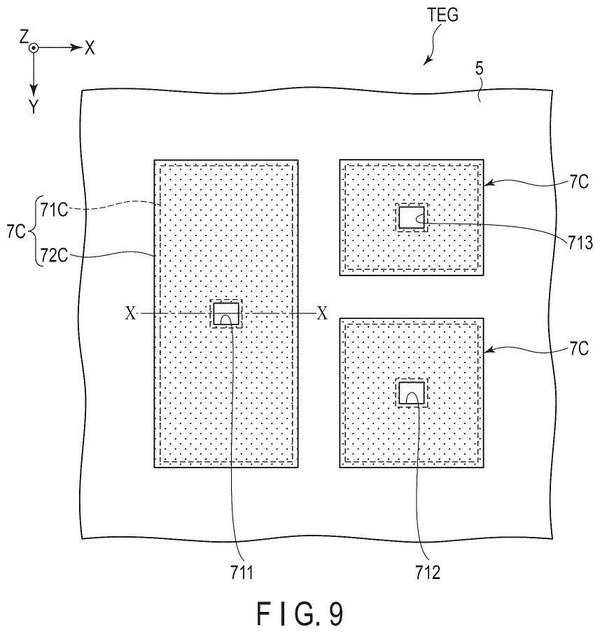

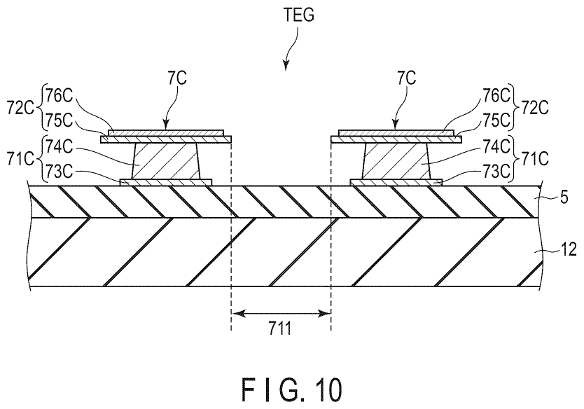

FIG. 9 is a schematic plan view showing another example of the configuration applicable to the test pattern TEG. FIG. 10 is a schematic cross-sectional view of the mother substrate MB including the test pattern TEG along the X-X line of FIG. 9. FIG. 10 omits the illustration of elements below the organic insulating layer 12. In the same manner as the configuration shown in FIG. 6 and FIG. 7, the configuration shown in FIG. 9 and FIG. 10 is applicable, for example, to the test pattern TEG for checking misalignment between the partition 6 and elements constituting the display element DE.

As shown in FIG. 9, the test pattern TEG is constituted by the rib layer 5 and a plurality of partitions 7C (the second partitions).

The rib layer 5 is provided across the panel portions PP and the margin area BA shown in FIG. 4.

The plurality of partitions 7C are provided in the margin area BA. For example, the outer shapes and the layout of the partitions 7C are the same as those of the partition apertures 601, 602, and 603 shown in FIG. 2.

In the example of FIG. 9, the plurality of partitions 7C have respective partition apertures 711, 712, and 713 (recessed portions) at their centers. A part of the partition 7C having the partition aperture 711 and the area overlapping the partition aperture 711 in plan view are areas (the target area, the first area) in which elements constituting the display element DE1 are provided. A part of the partition 7C having the partition aperture 712 and the area overlapping the partition aperture 712 in plan view are areas (the target area, the second area) in which elements constituting the display element DE2 are provided. A part of the partition 7C having the partition aperture 713 and the area overlapping the partition aperture 713 in plan view are areas (the target area) in which elements constituting the display element DE3 are provided.

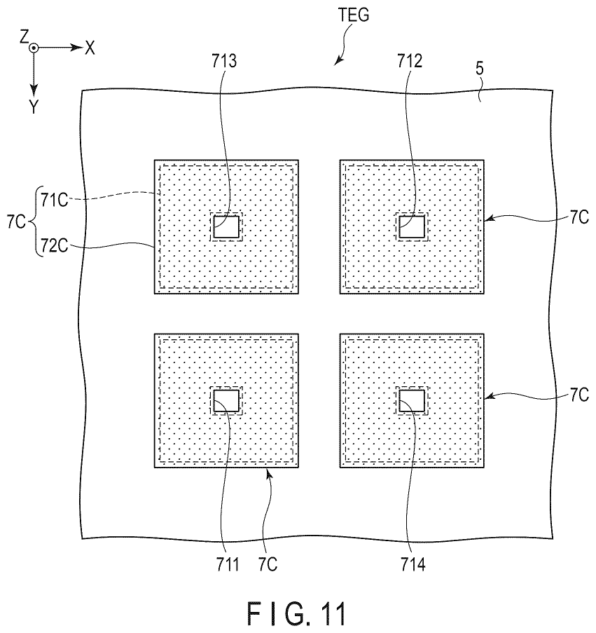

The figures show the case where the outer shapes and the layout of the partitions 7C are the same as those of the partition apertures 601, 602, and 603 shown in FIG. 2. For example, as shown in FIG. 11, the partitions 7C may have an outer shape and a layout different from those of the partition apertures 601, 602, and 603. FIG. 11 shows the case where the partitions 7C are provided with outer shapes and layouts different from those of the partition apertures 601, 602 and 603, another partition 7C having a partition aperture 714 corresponding to another color subpixel SP such as a white subpixel is further provided in addition to three partitions 7C having the respective partition apertures 711, 712 and 713 corresponding to the subpixels SP1, SP2 and SP3, and the partitions 7C have square outer shapes.

As shown in FIG. 9 and FIG. 10, each partition 7C includes a lower portion 71C (a bottom layer 73C and a stem layer 74C) and an upper portion 72C (a first top layer 75C and a second top layer 76C) in the same manner as the partition 6. Further, in the same manner as the partition 6, the partition 7C is also configured such that both end portions of the bottom layer 73C protrude relative to side surfaces of the stem layer 74C.

The lower portion 71C of the partition 7C is formed of the same material as the lower portion 61 of the partition 6. More specifically, the bottom layer 73C and the stem layer 74C are respectively formed of the same materials as the bottom layer 63 and the stem layer 64 of the partition 6. The thickness of the bottom layer 73C is equivalent to the thickness of the bottom layer 63 of the partition 6. Further, the thickness of the stem layer 74C is equivalent to the thickness of the stem layer 64 of the partition 6.

The upper portion 72C of the partition 7C is formed of the same material as the upper portion 62 of the partition 6. More specifically, the first top layer 75C and the second top layer 76C are respectively formed of the same materials as the first top layer 65 and the second top layer 66 of the partition 6. The thickness of the first top layer 75C is equivalent to the thickness of the first top layer 65 of the partition 6. The thickness of the second top layer 76C is equivalent to the thickness of the second top layer 66 of the partition 6.

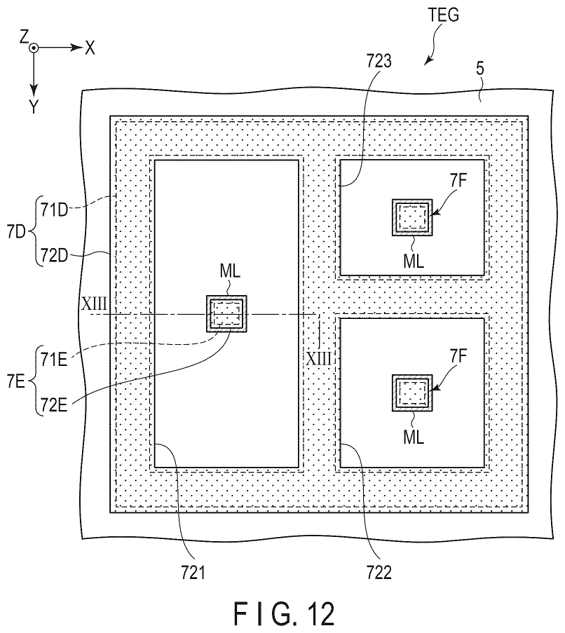

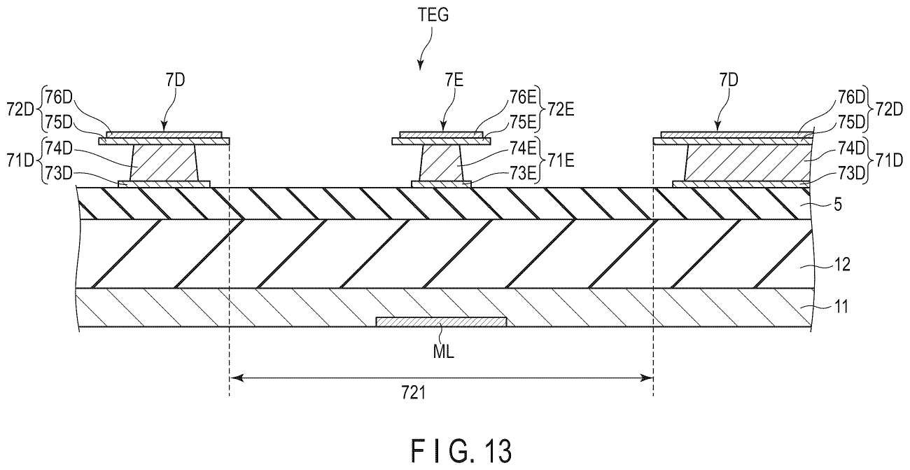

FIG. 12 is a schematic plan view showing another example of the configuration applicable to the test pattern TEG. FIG. 13 is a schematic cross-sectional view of the mother substrate MB including the test pattern TEG along the XIII-XIII line of FIG. 12. The configuration shown in FIG. 12 and FIG. 13 is applicable, for example, to the test pattern TEG for checking misalignment between metal lines (for example, the signal line SL) included in the circuit layer 11 and elements constituting the display element DE.

As shown in FIG. 12, the test pattern TEG is constituted by the rib layer 5, the partition 7D (the third partition), and a plurality of partitions 7E (the second partitions and the protrusion portions).

The rib layer 5 is provided across the panel portions PP and the margin area BA shown in FIG. 4.

The partition 7D is provided in the margin area BA. In the same manner as the partition 6, the partition 7D extends in the X-direction and the Y-direction and is formed in a lattice shape. In the example of FIG. 12, the partition 7D has respective partition apertures 721, 722, and 723. For example, the outer shapes and the layout of the partition apertures 721, 722, and 723 are the same as those of the partition apertures 601, 602, and 603 shown in FIG. 2. The partition 7E (described later) surrounded by the partition aperture 721 and the area overlapping the partition aperture 721 in plan view are the areas (the target area, the first area) in which elements constituting the display element DE1 are provided. The partition 7E (described later) surrounded by the partition aperture 722 and the area overlapping the partition aperture 722 in plan view are the areas (the target area, the second area) in which elements constituting the display element DE2 are provided. The partition 7E (described later) surrounded by the partition aperture 723 and the area overlapping the partition aperture 723 in plan view are the areas (the target area) in which elements constituting the display element DE3 are provided.

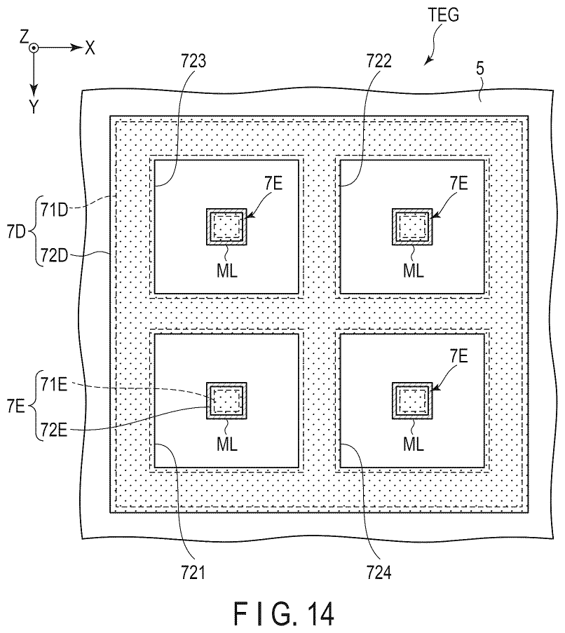

The figures show the case where the outer shapes and the layout of the partition apertures 721, 722, and 723 are the same as those of the partition apertures 601, 602, and 603 shown in FIG. 2. For example, as shown in FIG. 14, the partition 7D may have one or more partition apertures having an outer shape different from the partition apertures 601, 602, and 603. In FIG. 14, the partition 7D further has a partition aperture 724 corresponding to another color subpixel SP such as a white subpixel in addition to the partition apertures 721, 722, and 723 corresponding to the respective subpixels SP1, SP2 and SP3, and the outer shapes of the partition apertures 721, 722, 723, and 724 are square in this example.

In the example of FIG. 12, the plurality of partitions 7E are each provided to overlap the metal line ML included in the circuit layer 11 and are provided at the respective centers of the partition apertures 721, 722, and 723. The plurality of partitions 7E are surrounded by the respective partition apertures 721, 722, and 723. Each side length of the partition 7E is smaller than each side length of the metal line ML. Each side length of the partition 7E is smaller than the width of the partition 7D. Each side length of the partition 7E may be approximately equivalent to the width of the partition 7D.

As shown in FIG. 12 and FIG. 13, the partitions 7D and 7E each include lower portions 71D and 71E (bottom layers 73D and 73E and stem layers 74D and 74E) and upper portions 72D and 72E (first top layers 75D and 75E and second top layers 76D and 76E), in the same manner as the partition 6. Further, in the same manner as the partition 6, the partitions 7D and 7E are also configured such that both end portions of the bottom layers 73D and 73E protrude relative to side surfaces of the stem layers 74D and 74E.

The lower portions 71D and 71E of the partitions 7D and 7E are formed of the same materials as the lower portion 61 of the partition 6. More specifically, the bottom layers 73D and 73E and the stem layers 74D and 74E are respectively formed of the same materials as the bottom layer 63 and the stem layer 64 of the partition 6. The thicknesses of the bottom layers 73D and 73E are equivalent to the thickness of the bottom layer 63 of the partition 6. Further, the thicknesses of the stem layers 74D and 74E are equivalent to the thickness of the stem layer 64 of the partition 6.

The upper portions 72D and 72E of the partitions 7D and 7E are formed of the same materials as the upper portion 62 of the partition 6. More specifically, the first top layers 75D and 75E and the second top layers 76D and 76E are respectively formed of the same materials as the first top layer 65 and the second top layer 66 of the partition 6. The thicknesses of the first top layers 75D and 75E are equivalent to the thickness of the first top layer 65 of the partition 6. The thicknesses of the second top layers 76D and 76E are equivalent to the thickness of the second top layer 66 of the partition 6.

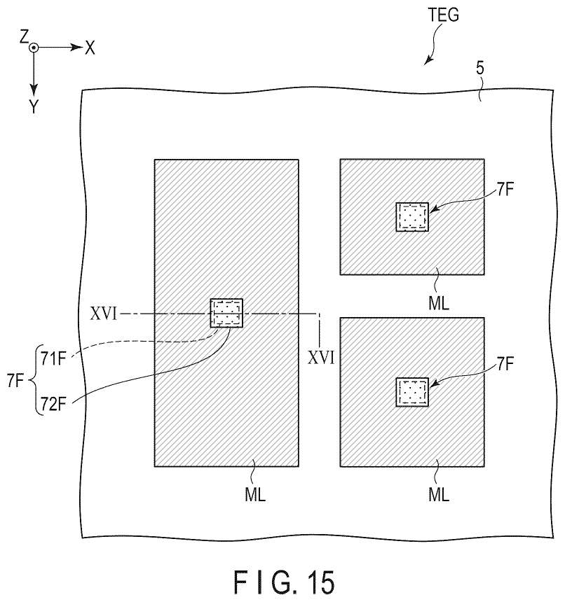

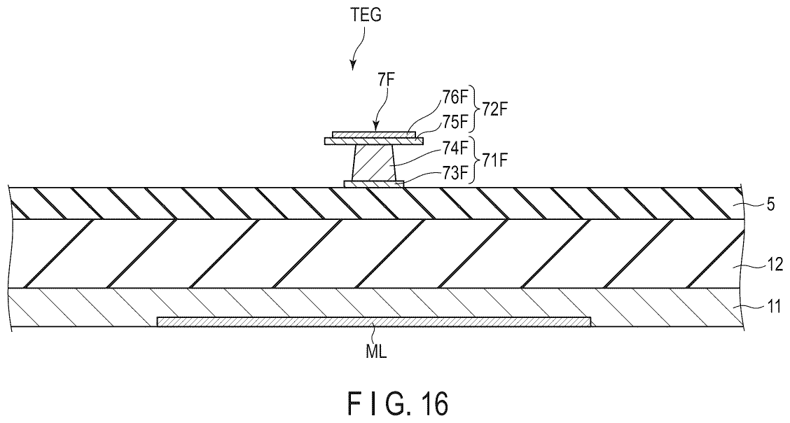

FIG. 15 is a schematic plan view showing another example of the configuration applicable to the test pattern TEG. FIG. 16 is a schematic cross-sectional view of the mother substrate MB along the XVI-XVI line of FIG. 15. In the same manner as the configuration shown in FIG. 12 and FIG. 13, the configuration shown in FIG. 15 and FIG. 16 is applicable, for example, to the test pattern TEG for checking misalignment between metal lines (for example, the signal line SL) included in the circuit layer 11 and elements constituting the display element DE.

As shown in FIG. 15, the test pattern TEG is constituted by the rib layer 5 and a plurality of partitions 7F (the second partitions and the protrusion portions).

The rib layer 5 is provided across the panel portions PP and the margin area BA shown in FIG. 4.

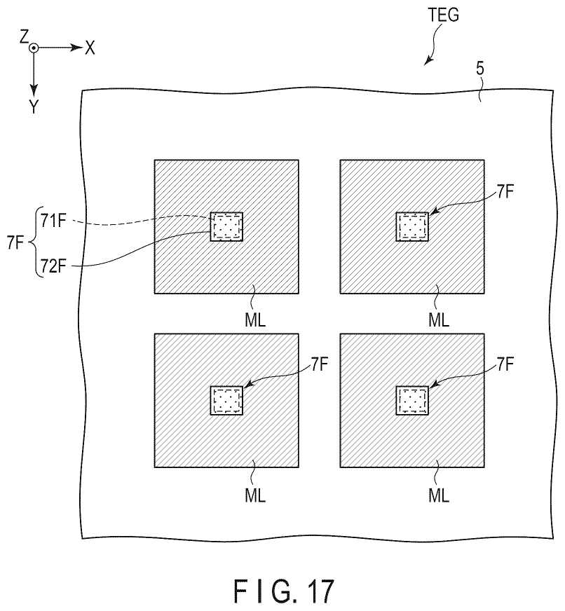

The plurality of partitions 7F are provided in the margin area BA. In the example of FIG. 15, three partitions 7F are each located at positions overlapping the center of the metal line ML included in the circuit layer 11. Each side length of the partition 7F is smaller than each side length of the metal line ML. The areas overlapping three metal lines ML in plan view are areas (the target area, the first area, and the second area) in which elements constituting the display element DE are provided. The figures show the arrangement of the partitions 7F in the case where the outer shapes and layouts of the metal lines ML are the same as those of the partition apertures 601, 602, and 603 shown in FIG. 2. When the outer shapes and layout of the metal lines ML are the same as those shown in FIG. 17, four partitions 7F are provided at positions overlapping the centers of the metal lines ML in the test pattern TEG.

As shown in FIG. 15 and FIG. 16, each of the partitions 7F includes a lower portion 71F (a bottom layer 73F and a stem layer 74F) and an upper portion 72F (a first top layer 75F and a second top layer 76F), in the same manner as the partition 6. Further, in the same manner as the partition 6, the partition 7F is also configured such that both end portions of the bottom layer 73F protrude relative to side surfaces of the stem layer 74F.

The lower portion 71F of the partition 7F is formed of the same material as the lower portion 61 of the partition 6. More specifically, the bottom layer 73F and the stem layer 74F are respectively formed of the same materials as the bottom layer 63 and the stem layer 64 of the partition 6. The thickness of the bottom layer 73F is equivalent to the thickness of the bottom layer 63 of the partition 6. Further, the thickness of the stem layer 74F is equivalent to the thickness of the stem layer 64 of the partition 6.

The upper portion 72F of the partition 7F is formed of the same material as the upper portion 62 of the partition 6. More specifically, the first top layer 75F and the second top layer 76F are respectively formed of the same materials as the first top layer 65 and the second top layer 66 of the partition 6. The thickness of the first top layer 75F is equivalent to the thickness of the first top layer 65 of the partition 6. The thickness of the second top layer 76F is equivalent to the thickness of the second top layer 66 of the partition 6.

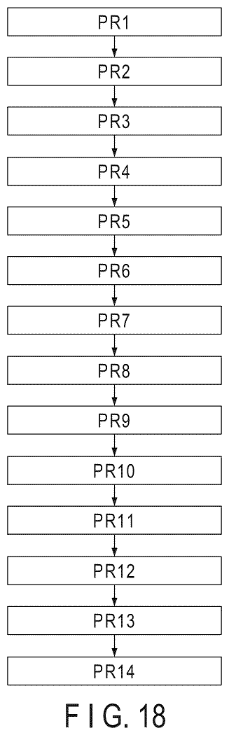

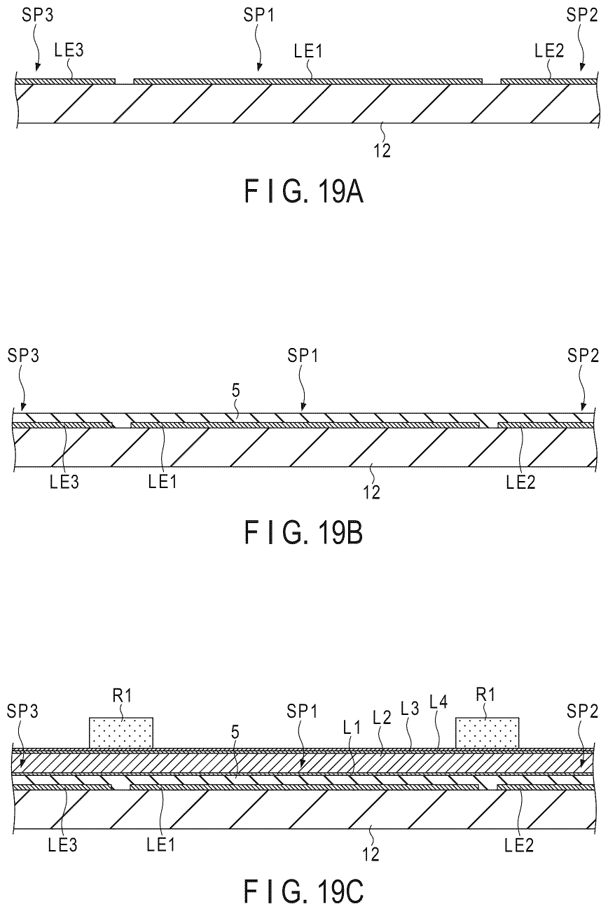

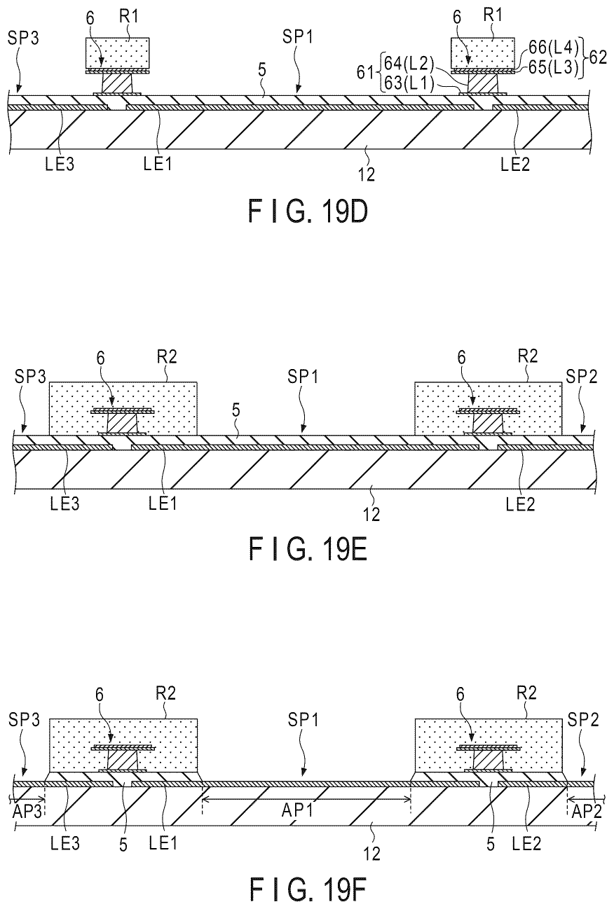

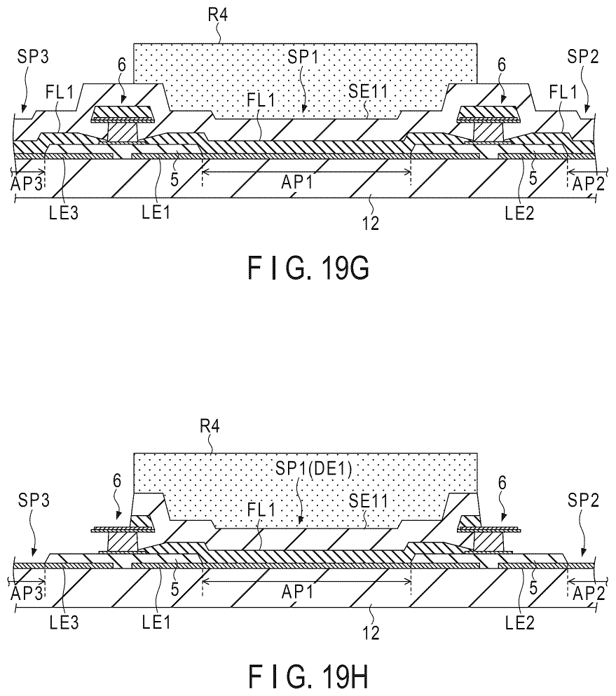

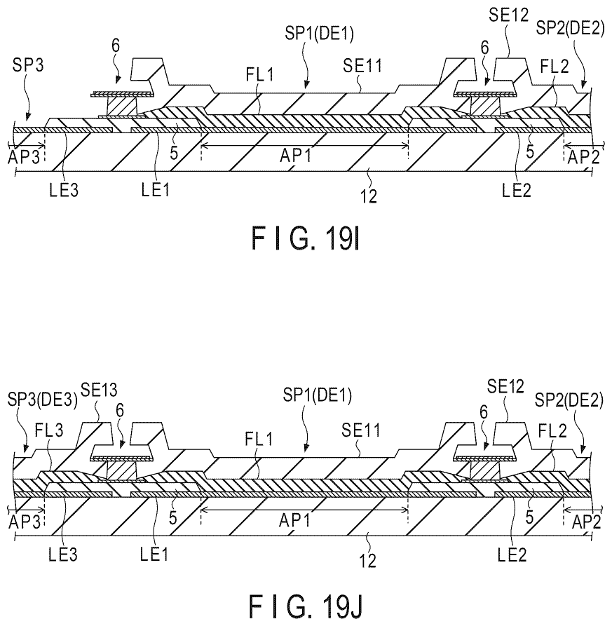

The following will describe an example of the manufacturing method of the display device DSP. FIG. 18 is a flowchart showing an example of the manufacturing method of the display device DSP. FIG. 19A to FIG. 19J are schematic cross-sectional views showing manufacturing processes of the panel portions PP on the mother substrate MB. FIG. 19A to FIG. 19J mainly focus on the display area DA and omit the illustration of elements under the organic insulating layer 12.

In the formation of the panel portions PP, first, the circuit layer 11 and the organic insulating layer 12 are formed on the substrate 10 of the mother substrate MB (the process PR1 in FIG. 18). Next, as shown in FIG. 19A, the lower electrodes LE1, LE2, and LE3 are formed on the organic insulating layer 12 (the process PR2 in FIG. 18).

Subsequently, as shown in FIG. 19B, the rib layer 5 covering the lower electrodes LE1, LE2, and LE3 is formed on the entire mother substrate MB (the process PR3 in FIG. 18). At this time, the pixel apertures AP1, AP2, and AP3 are not provided in the rib layer 5. The rib layer 5 can be formed by chemical vapor deposition (CVD).

After the formation of the rib layer 5, processes for forming the partition 6 are performed (the processes PR4 and PR5 in FIG. 18). In the process PR4, as shown in FIG. 19C, a first layer L1 to be processed into the bottom layer 63, a second layer L2 to be processed into the stem layer 64, a third layer L3 to be processed into the first top layer 65, and a fourth layer L4 to be processed into the second top layer 66 are sequentially formed over the entire mother substrate MB. Further, a resist R1 is provided on the fourth layer L4. The resist R1 is patterned into the shape of the partition 6. The first layer L1, the second layer L2, the third layer L3, and the fourth layer L4 can be formed by sputtering, for example.

In the subsequent process PR5, the first layer L1, the second layer L2, the third layer L3, and the fourth layer L4 are patterned using the resist R1 as a mask. In one example, the first layer L1 is formed of a titanium nitride, the second layer L2 is formed of aluminum, the third layer L3 is formed of titanium, and the fourth layer L4 is formed of an ITO. In this case, the process PR5 may include wet etching for removing the part exposed from the resist R1 of the fourth layer L4, dry etching for removing the parts exposed from the resist R1 of the first layer L1, the second layer L2, and the third layer L3, and wet etching for reducing the width of the second layer L2. Types of etching performed in the process PR5 are selected as appropriate according to the structure and materials of the partition 6.

The process PR5 completes the formation of the partition 6 in the display area DA as shown in FIG. 19D. After the formation of the partition 6, the resist R1 is removed (stripped). During the wet etching that reduces the width of the second layer L2, the second top layer 66 (the fourth layer L4) may also be slightly corroded. When this corrosion occurs, the width of the second top layer 66 becomes smaller than the width of the first top layer 65.

Next, the process for providing the pixel apertures AP1, AP2, and AP3 is performed (the process PR6 in FIG. 18). In the process PR6, a resist R2 covering the partition 6 is formed as shown in FIG. 19E. Further, dry etching for the rib layer 5 is performed using the resist R2 as a mask. Thus, as shown in FIG. 19F, the pixel apertures AP1, AP2, and AP3 are formed in the rib layer 5. The respective lower electrodes LE1, LE2, and LE3 are exposed from the pixel apertures AP1, AP2, and AP3. After these dry etching processes, the resist R2 is removed (stripped).

After the process PR6, a process for removing the rib layer 5 in the terminal portion T shown in FIG. 1 is performed (the process PR7 in FIG. 18).

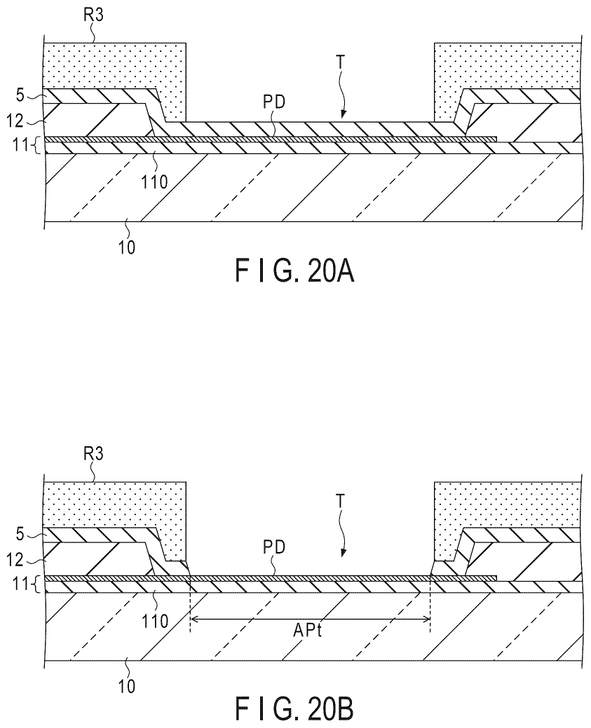

FIG. 20A and FIG. 20B are schematic cross-sectional views of the terminal portion T for describing the process PR7. As shown in these figures, the terminal portion T comprises a conductive pad PD. The pad PD is provided on an insulating layer 110 formed, for example, of an inorganic insulating material. The pad PD and the insulating layer 110 are included in the circuit layer 11 shown in FIG. 3, for example. For example, a peripheral portion of the pad PD is covered with the organic insulating layer 12.

As shown in FIG. 20A, the pad PD is covered with the rib layer 5 at the time of the completion of the process PR6. In the process PR7, a resist R3 having an aperture above the pad PD is provided on the rib layer 5. Further, dry etching for the rib layer 5 is performed using the resist R3 as a mask. As shown in FIG. 20B, this process forms a terminal aperture APt in the rib layer 5. The pad PD is exposed from the terminal aperture APt. After these dry etching processes, the resist R3 is removed (stripped).

After the process PR7, the process for forming the display element DE1 is performed (the process PR8 in FIG. 18). As shown in FIG. 19G, in the formation of the display element DE1, the stacked film FL1 and the sealing layer SE11 are formed first. As shown in FIG. 3, the stacked film FL1 includes the organic layer OR1 contacting the lower electrode LE1 through the pixel aperture AP1, the upper electrode UE1 covering the organic layer OR1, and the cap layer CP1 covering the upper electrode UE1. For example, the organic layer OR1, the upper electrode UE1, and the cap layer CP1 may be formed by vapor deposition. For example, the sealing layer SE11 may be formed by CVD.

The stacked film FL1 and the sealing layer SE11 are formed not in only the display area DA of each panel portion PP but also on the entire mother substrate MB including the surrounding area SA and the margin area BA. The partition 6 having an overhang shape divides the stacked film FL1 into a plurality of parts. The sealing layer SE11 continuously covers these parts, into which the stacked film FL1 has been divided, and the partition 6.

Subsequently, the stacked film FL1 and the sealing layer SE11 are patterned. As shown in FIG. 19G, a resist R4 is provided on the sealing layer SE11 in this patterning. The resist R4 covers the subpixel SP1 and a part of the partition 6 around the subpixel SP1.

Thereafter, the etching process using the resist R4 as a mask is performed. As shown in FIG. 19H, parts exposed from the resist R4 of the stacked film FL1 and the sealing layer SE11 are removed. That is, parts overlapping the lower electrode LE1 of the stacked film FL1 and the sealing layer SE11 remain. The other parts are removed. Thus, the display element DE1 is formed in the subpixel SP1. For example, in the surrounding area SA and the margin area BA, the stacked film FL1 and the sealing layer SE11 are removed by the etching process. This etching process may include wet etching and dry etching performed in order for the sealing layer SE11, the cap layer CP1, the upper electrode UE1, and the organic layer OR1. After these etching processes, the resist R4 is removed (stripped).

After the process PR8, the process for forming the display element DE2 is performed (the process PR9 in FIG. 18). The display element DE2 can be formed by the same procedure as that of the display element DE1. That is, in the formation of the display element DE2, the stacked film FL2 and the sealing layer SE12 are formed on the entire mother substrate MB. As shown in FIG. 3, the stacked film FL2 includes the organic layer OR2 contacting the lower electrode LE2 through the pixel aperture AP2, the upper electrode UE2 covering the organic layer OR2, and the cap layer CP2 covering the upper electrode UE2.

The organic layer OR2, the upper electrode UE2, and the cap layer CP2 may be formed by, for example, vapor deposition. The sealing layer SE12 may be formed by, for example, CVD. The partition 6 having an overhang shape divides the stacked film FL2 into a plurality of parts. The sealing layer SE12 continuously covers these parts, into which the stacked film FL2 has been divided, and the partition 6. Patterning these stacked film FL2 and sealing layer SE12 forms the display element DE2 in the subpixel SP2 as shown in FIG. 19I. For example, in the surrounding area SA and the margin area BA, the stacked film FL2 and the sealing layer SE12 are removed by the etching process of this patterning.

After the process PR9, the process for forming the display element DE3 is performed (the process PR10 in FIG. 18). The display element DE3 can be formed by the same procedures as those of the display elements DE1 and DE2. That is, in the formation of the display element DE3, the stacked film FL3 and the sealing layer SE13 are formed on the entire mother substrate MB. As shown in FIG. 3, the stacked film FL3 includes the organic layer OR3 contacting the lower electrode LE3 through the pixel aperture AP3, the upper electrode UE3 covering the organic layer OR3, and the cap layer CP3 covering the upper electrode UE3.

The organic layer OR3, the upper electrode UE3, and the cap layer CP3 may be formed by, for example, vapor deposition. The sealing layer SE13 may be formed by, for example, CVD. The partition 6 having an overhang shape divides the stacked film FL3 into a plurality of parts. The sealing layer SE13 continuously covers these parts, into which the stacked film FL3 has been divided, and the partition 6. As shown in FIG. 19J, patterning these stacked film FL3 and sealing layer SE13 forms the display element DE3 in the subpixel SP3. For example, the etching in this patterning removes the stacked film FL3 and the sealing layer SE13 in the surrounding area SA and the margin area BA.

Here, the above description assumes that the display elements DE1, DE2, and DE3 are formed in this order. However, the display elements DE1, DE2, and DE3 may be formed in another order.

After the formations of the display elements DE1, DE2, and DE3, the resin layer RS1, the sealing layer SE2, and the resin layer RS2 shown in FIG. 3 are sequentially formed (the process PR11 in FIG. 18). Further, each panel portion PP is cut out from the mother substrate MB along the cut line CL1 (the process PR12 in FIG. 18).

Thereafter, each panel portion PP undergoes inspection (the process PR13 in FIG. 18). This inspection includes illumination inspection of the display elements DE1, DE2, and DE3 using the inspection pad provided in the inspection area TA and the like. After this inspection, the inspection area TA is cut out along the cut line CL2 (the process PR14 in FIG. 18). This completes the display panel PNL.

The partitions 7A to 7F are formed by the same processes PR4 and PR5 as the partition 6. That is, in the processes PR4 and PR5, the bottom layers 73A to 73F are formed on the rib layers 5, the stem layers 74A to 74F are formed on the bottom layers 73A to 73F, the first top layers 75A to 75F are formed on the stem layers 74A to 74F, and the second top layers 76A to 76F are formed on the first top layers 75A to 75F.

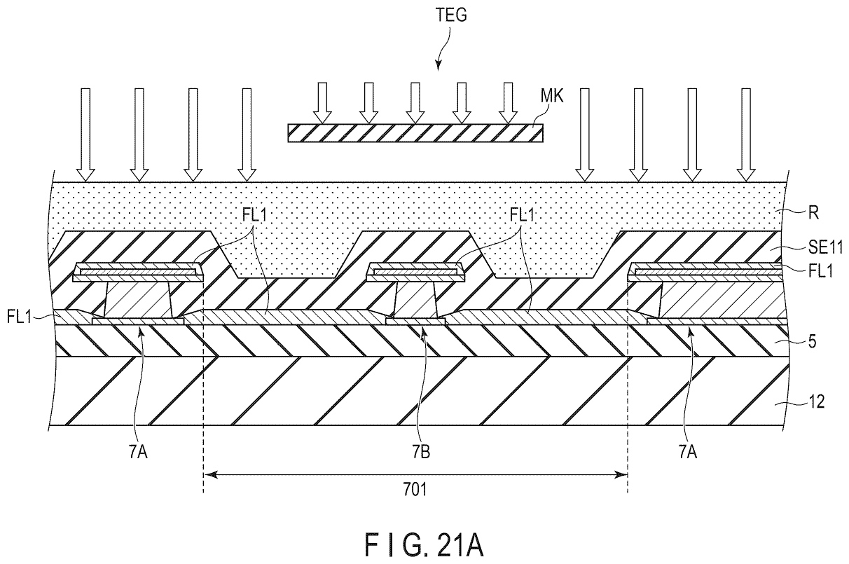

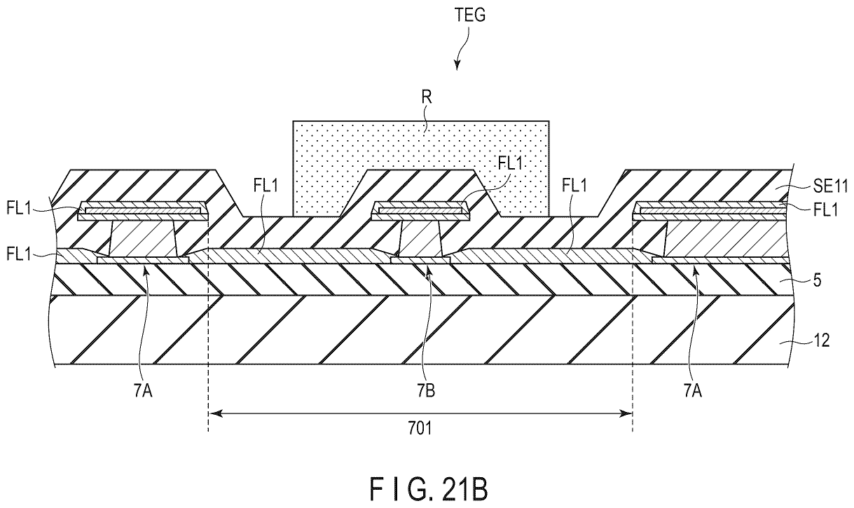

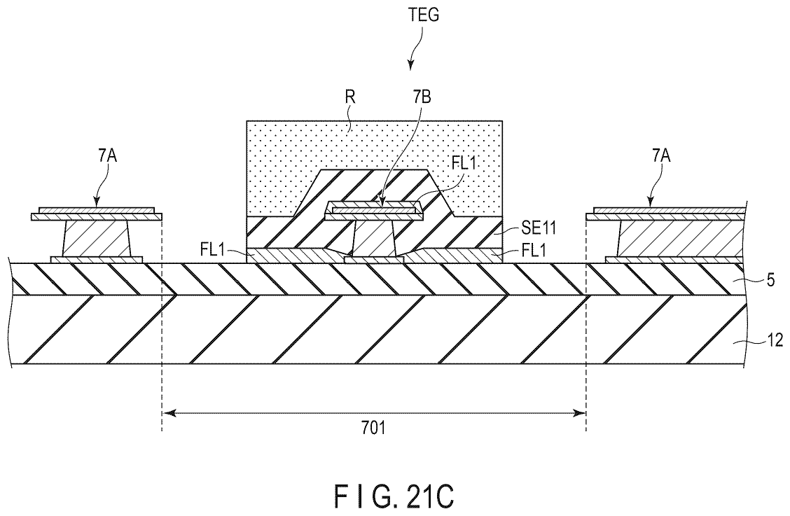

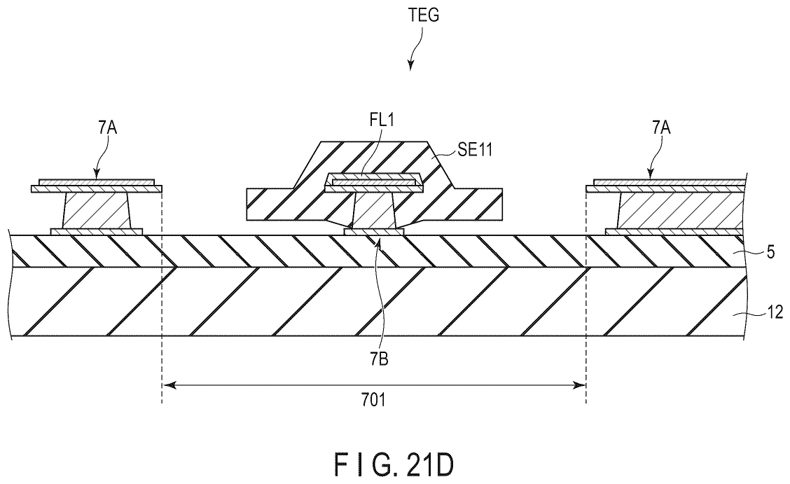

FIG. 21A to FIG. 21D are schematic cross-sectional views showing cases where the process PR8 for forming the display element DE1 is performed on the test pattern TEG of the configuration shown in FIG. 6 and FIG. 7. This cross-section corresponds to the same position as in FIG. 7, and omits the illustration of components below the organic insulating layer 12.

In the process PR8, the stacked film FL1 and the sealing layer SE11 are formed in the partition aperture 701 as shown in FIG. 21A. A resist R corresponding to the resist R4 shown in FIG. 19H is formed on the stacked film FL1 and the sealing layer SE11. Further, the resist R is exposed to light using a mask MK as shown by several arrows. The mask MK has apertures in areas except above the partition 7B. The resist R is, for example, a positive resist. Thus, parts exposed to light of the resist R is removed by a development process as shown in FIG. 21B.

Thereafter, the etching process using the resist R as a mask is performed. As shown in FIG. 21C, this process removes parts exposed from the resist R of the stacked film FL1 and the sealing layer SE11. The stacked film FL1 and the sealing layer SE11 provided on the partition 7B and the stacked film FL1 and the sealing layer SE11 provided on side surfaces of the partition 7B are covered with the resist R and are not removed in this etching step. The sealing layer SE11 provided around the partitions 7B adheres strongly to the partitions 7B and is not stripped with the resist R in the removal (stripping) of the resist R following this process. Accordingly, as shown in FIG. 21D, the sealing layer SE11 provided around the partitions 7B and the stacked film FL1 provided on the partitions 7B remain in the test pattern TEG after the stripping of the resist R. The stacked film FL1 provided on the side surfaces of the partitions 7B is removed by interfacial etching by a stripping solution used to strip the resist R or by subsequent etching processes.

In the process PR9, the same processes as in FIG. 21A to FIG. 21D are performed for the partition aperture 702. In the process PR10, the same processes as in FIG. 21A to FIG. 21D are performed for the partition aperture 703. In both of the processes, the sealing layers SE12 and SE13 provided around the partitions 7B adhere strongly to the partitions 7B and are not stripped with the resist R in the following processes.

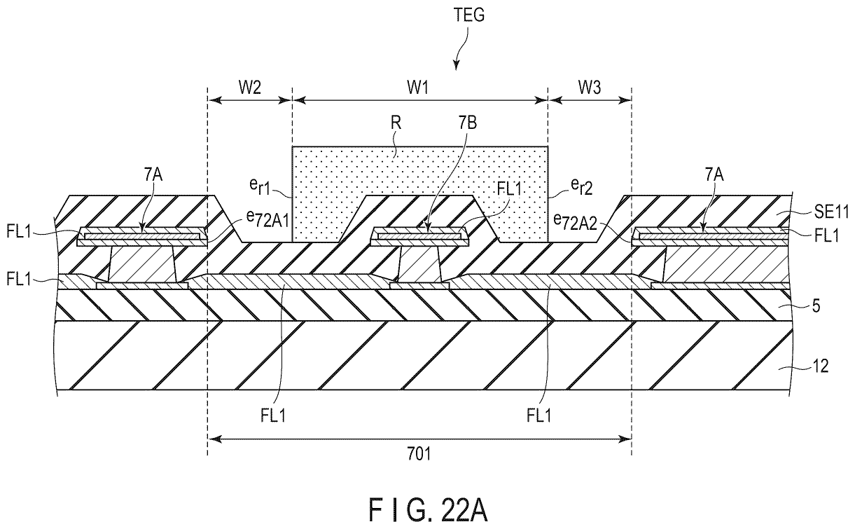

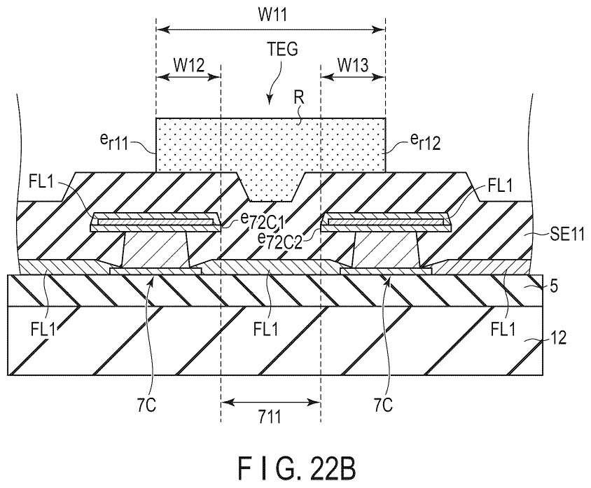

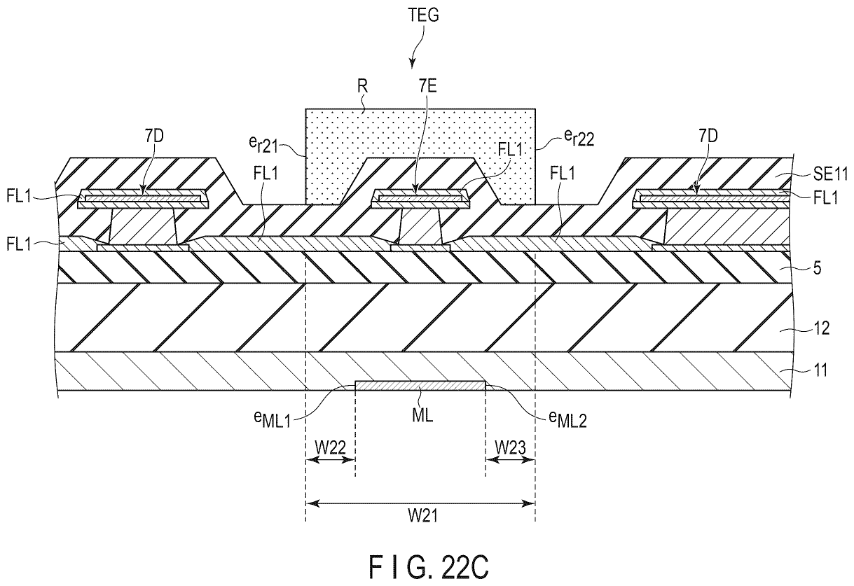

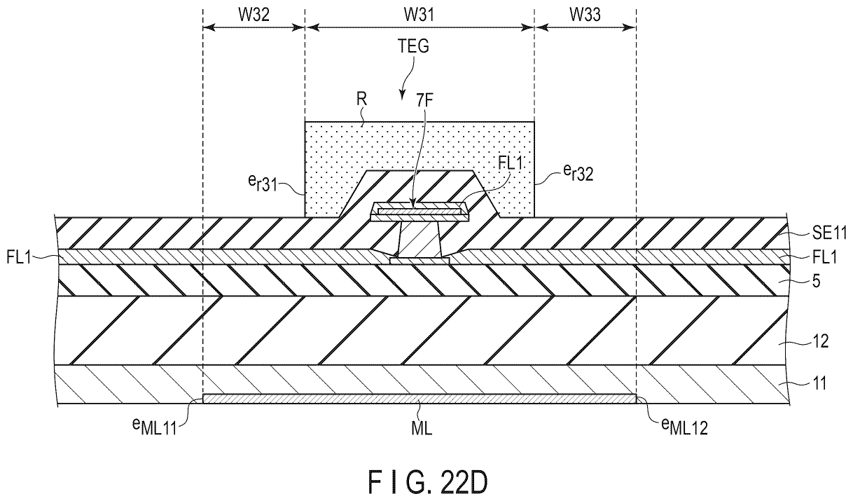

The above describes the case where the processes PR8, PR9, and PR10 are performed on the test pattern TEG of the configuration shown in FIG. 6 and FIG. 7. In a case where the processes PR8, PR9, and PR10 are performed on the test pattern TEG of the configuration shown in FIG. 9 and FIG. 10 as well, the partition apertures 711, 712, and 713 formed in the partitions 7C and the sealing layers SE11, SE12, and SE13 provided around the partition apertures 711, 712, and 713 adhere strongly to the partition 7C and are not stripped together with the resist R in the removal process of the resist R after the etching process. The stacked films FL1, FL2, and FL3 provided on the partitions 7C (for an example in which the stacked film FL1 is provided on the partition 7C, see FIG. 22B described later) are removed by interfacial etching of a stripping solution for stripping the resist R or by the following etching process.

In a case where the processes PR8, PR9, and PR10 are performed on the test pattern TEG of the configuration shown in FIG. 12 and FIG. 13 as well, the sealing layers SE11, SE12, and SE13 provided around the partition 7E adhere strongly to the partition 7E and are not stripped together with the resist R in the removal process of the resist R after the etching process. The stacked films FL1, FL2, and FL3 provided on the side surfaces of the partitions 7E (for an example in which the stacked film FL1 is provided on the side surfaces the partition 7E, see FIG. 22C described later) are removed by interfacial etching of a stripping solution for stripping the resist R or by the following etching process.

Further, in a case where the processes PR8, PR9, and PR10 are performed on the test pattern TEG of the configuration shown in FIG. 15 and FIG. 16 as well, the sealing layers SE11, SE12, and SE13 provided around the partition 7F adhere strongly to the partition 7F and are not stripped together with the resist R in the removal process of the resist R after the etching process. The stacked films FL1, FL2, and FL3 provided on the side surfaces of the partitions 7F (for an example in which the stacked film FL1 is provided on the side surfaces the partition 7F, see FIG. 22D described later) are removed by interfacial etching of a stripping solution for stripping the resist R or by the following etching process.

Next, the following will describe a measurement process for the test pattern TEG according to the present embodiment. The measurement process for the test pattern TEG of the present embodiment is performed, for example, after the exposure of the resist R corresponding to the resist R4 shown in FIG. 19H using the mask MK in the process PR8.

FIG. 22A to FIG. 22D are schematic cross-sectional views showing one example of the measurement process. FIG. 22A shows one example of the measurement process for the test pattern TEG having the configuration shown in FIG. 6 and FIG. 7. FIG. 22B shows one example of the measurement process for the test pattern TEG having the configuration shown in FIG. 9 and FIG. 10. FIG. 22C shows one example of the measurement process for the test pattern TEG having the configuration shown in FIG. 12 and FIG. 13. FIG. 22D shows one example of the measurement process for the test pattern TEG having the configuration shown in FIG. 15 and FIG. 16.

The measurement process for the test pattern TEG having the configuration shown in FIG. 6 and FIG. 7 measures a line width W1 of the resist R, a length (width) W2 from one end portion eᵣ₁ of the resist R to the other end portion e_{72A1} of the upper portion 72A of the partition 7A, and a length (width) W3 from the other end portion eᵣ₂ of the resist R to one end portion e_{72A2} of the upper portion 72A of the partition 7A as shown in FIG. 22A. The measurement of the widths W1, W2, and W3 are performed, for example, using an atomic force microscope (AFM) or a white-light interference microscope. Alternatively, the widths W1, W2, and W3 may be measured by analyzing an image obtained by photographing the test pattern TEG in plan view. The above describes the case where the widths W1, W2, and W3 in the X-direction are measured with reference to the X-Z cross-section of FIG. 22A. The widths in the Y-direction are measured in the same manner.

The measurement process for the test pattern TEG having the configuration shown in FIG. 9 and FIG. 10 measures a line width W11 of the resist R, a length (width) W12 from one end portion eᵣ₁₁ of the resist R to the other end portion e_{72C1} on the partition aperture 711 side of the upper portion 72C of the partition 7C, and a length (width) W13 from the other end portion eᵣ₁₂ of the resist R to one end portion e_{72C2} on the partition aperture 711 side of the upper portion 72C of the partition 7C as shown in FIG. 22B. The measurement of the widths W11, W12, and W13 are performed, for example, using an atomic force microscope (AFM) or a white-light interference microscope. Alternatively, the widths W11, W12, and W13 may be measured by analyzing an image obtained by photographing the test pattern TEG in plan view. The above describes the case where the widths W11, W12, and W13 in the X-direction are measured with reference to the X-Z cross-section of FIG. 22B. The widths in the Y-direction are measured in the same manner.

The measurement process for the test pattern TEG having the configuration shown in FIG. 12 and FIG. 13 measures a line width W21 of the resist R, a length (width) W22 from one end portion eᵣ₂₁ of the resist R to one end portion e_{ML1} of the metal line ML, and a length (width) W23 from the other end portion eᵣ₂₂ of the resist R to the other end portion e_{ML2} of the metal line ML as shown in FIG. 22C. The measurement of the widths W21, W22, and W23 are performed, for example, using an atomic force microscope (AFM) or a white-light interference microscope. Alternatively, the widths W21, W22, and W23 may be measured by analyzing an image obtained by photographing the test pattern TEG in plan view. The above describes the case where the widths W21, W22, and W23 in the X-direction are measured with reference to the X-Z cross-section of FIG. 22C. The widths in the Y-direction are measured in the same manner.

The measurement process for the test pattern TEG having the configuration shown in FIG. 15 and FIG. 16 measures a line width W31 of the resist R, a length (width) W32 from one end portion eᵣ₃₁ of the resist R to one end portion e_{ML11} of the metal line ML, and a length (width) W33 from the other end portion eᵣ₃₂ of the resist R to the other end portion e_{ML12} of the metal line ML as shown in FIG. 22D. The measurement of the widths W31, W32, and W33 are performed, for example, using an atomic force microscope (AFM) or a white-light interference microscope. Alternatively, the widths W31, W32, and W33 may be measured by analyzing an image obtained by photographing the test pattern TEG in plan view. The above describes the case where the widths W31, W32, and W33 in the X-direction are measured with reference to the X-Z cross-section of FIG. 22D. The widths in the Y-direction are measured in the same manner.

These measurement processes enable checking misalignment between the partition 6 and elements constituting the display element DE, and misalignment between the metal line ML functioning as a reference layer and elements constituting the display element DE before the etching process. Further, these measurement processes enable checking whether the resist R is applied to a correct position. For example, when at least one of the widths deviates from a predetermined allowable range, manufacturing processes after the measurement process may be stopped. Alternatively, the position of the resist R may be adjusted (specifically, to adjust the position of the resist R, the resist R may be stripped once, then applied again, and a developing process may be performed again after adjusting the position of the mask MK) and the manufacturing processes may be continued.

The measurement process for the test pattern TEG is also performed in the same manner after the exposure of the resist R using the mask MK in the processes PR9 and PR10.

Further, the measurement process for the test pattern TEG may be performed again after the stripping of the resist R in the processes PR8, PR9, and PR10. In this case, the measurement process for the test pattern TEG is performed with respect to the sealing layers SE11, SE12, and SE13 instead of the resist R.

For example, the measurement process performed after the stripping of the resist R in the process PR8 for the test pattern TEG having the configuration shown in FIG. 6 and FIG. 7 measures not the line widths of the resist R but the line width of the sealing layer SE11 shown in FIG. 21D, a length from one end of the sealing layer SE11 to an end portion of the upper portion 72A of the partition 7A, and a length from the other end portion of the sealing layer SE11 to an end portion of the upper portion 72A of the partition 7A.

The following assumes a test pattern where the partition 7B is not provided at the center of the partition aperture 701, as a comparative example. In this test pattern, for example, the measurement process with respect to the sealing layer SE11 after the stripping of the resist R in the process PR8 fails. This failure derives from that the stacked film FL1 is stripped from the rib layer 5 due to interfacial etching of a stripping solution for stripping the resist R and thus the sealing layer SE11 provided on the stacked film FL1 is also removed together with the resist R. In contrast, in the test pattern TEG according to the present embodiment, the partition 7B is provided at the center of the partition aperture 701. Thus, the present embodiment enables the adhesion of the sealing layer SE11 to the partition 7B such that the sealing layer SE11 is not removed together with the resist R at the time of the stripping of the resist R. Thus, the present embodiment enables the measurement process with respect to the sealing layer SE11.

The above describes a case where the measurement process for the test pattern TEG having the configuration shown in FIG. 6 and FIG. 7 is performed after the striping of the resist R in the process PR8. The measurement process for the test pattern TEG having the configuration shown in FIG. 6 and FIG. 7 and performed after the stripping of the resist R in the processes PR9 and PR10 can be performed in the same manner. Further, the measurement process for the test pattern TEG having another configuration and performed after the stripping of the resist R in the processes PR8, PR9, and PR10 can be performed in the same manner.

These measurement processes may be performed for each of the plurality of test patterns TEG dispersed on the mother substrate MB as shown in FIG. 4. Performing the measurement in this manner can suppress variation in measurements depending on the position on the mother substrate MB. In another example, the measurement process may be performed for some of the test patterns TEG.

As described above, regardless of whether the test pattern TEG has the configuration shown in FIG. 6 and FIG. 7, the configuration shown in FIG. 9 and FIG. 10, the configuration shown in FIG. 12 and FIG. 13, or the configuration shown in FIG. 15 and FIG. 16, the present embodiment allows the sealing layers SE11, SE12, and SE13 to remain on the test pattern TEG even after the stripping of the resist R in the processes PR8, PR9, and PR10 as described above and thus enables the measurement processes with respect to the sealing layers SE11, SE12, and SE13.

Stable measurement of each of the above widths requires no contamination adhering to the test pattern TEG at the time of the measurement process. The inventors have evaluated how much contamination adheres to the test pattern TEG having the configuration shown in FIG. 6 and FIG. 7, the test pattern TEG having the configuration shown in FIG. 9 and FIG. 10, the test pattern TEG having the configuration shown in FIG. 12 and FIG. 13, and the test pattern TEG having the configuration shown in FIG. 15 and FIG. 16. The inventors have concluded that the test pattern TEG having the configuration shown in FIG. 9 and FIG. 10 is least susceptible to contamination. Therefore, the test pattern TEG having the configuration shown in FIG. 9 and FIG. 10 is preferable for stably enabling the measurement processes with respect to the sealing layers SE11, SE12, and SE13 (the test pattern TEG in which the plurality of partitions 7C provided in the margin area BA each have a partition aperture (recessed portions)).

As described above, the present embodiment enables efficient and highly accurate inspection during manufacture of the display device DSP. Various desirable effects can be obtained from the embodiment in addition to the effects explained here.

All of the display devices, the mother substrates, and manufacturing methods thereof that can be implemented by a person of ordinary skill in the art through arbitrary design changes to the display devices, the mother substrates, and manufacturing methods thereof disclosed above as each embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is

1. A manufacturing method of a mother substrate, the method comprising steps of:
preparing a substrate including a plurality of panel portions each having a display area and a surrounding area around the display area, and a margin area around the plurality of panel portions;
forming a lower electrode in the display area;
forming a rib layer covering the panel portion and the margin area;
forming, in the display area, a first partition including a lower portion and an upper portion having an end portion protruding relative to a side surface of the lower portion;
forming, in the margin area, a second partition including the lower portion and the upper portion;
forming, in the panel portion and the margin area, a first stacked film at least including an organic layer of a first color and a first sealing layer covering the first stacked film; and
etching for removing, among the first stacked film and the first sealing layer formed in the panel portion and the margin area, the first stacked film and the first sealing layer that are formed outside a target area in which the organic layer of the first color is provided, wherein
the etching does not remove parts that are formed on the second partition or on a side surface of the second partition of the first stacked film and the first sealing layer in the target area in the margin area.

2. The manufacturing method of claim 1, further comprising a step of:
providing a resist from which portions outside the target area are exposed before the etching, wherein
the etching with the resist provided does not remove the parts of the first stacked film and the first sealing layer.

3. The manufacturing method of claim 2, further comprising a step of:
forming a third partition including the lower portion and the upper portion and surrounding the target area in the margin area, before the forming of the first stacked film and the first sealing layer, wherein
the second partition is located at a center of the target area surrounded by the third partition.

4. The manufacturing method of claim 3, further comprising a step of:
removing the resist after the etching, wherein
parts formed on the second partition of the first stacked film and parts adhering to the second partition of the first sealing layer remain in the target area in the margin area.

5. The manufacturing method of claim 3, further comprising a step of:
measuring a width of the resist and a length from an end portion of the resist to an end portion of the upper portion included in the third partition, between the etching and the removing of the resist.

6. The manufacturing method of claim 3, further comprising a step of:
measuring a width of the first sealing layer adhering to the second partition and a length from an end portion of the first sealing layer adhering to the second partition to an end portion of the upper portion included in the third partition, after the removing of the resist.

7. The manufacturing method of claim 2, wherein
the second partition has an aperture at a center of the second partition, and
the aperture overlaps the target area in the margin area in plan view.

8. The manufacturing method of claim 7, further comprising a step of:
removing the resist after the etching, wherein
parts formed in the aperture of the first stacked film and parts adhering to the second partition of the first sealing layer remain in the target area in the margin area.

9. The manufacturing method of claim 7, further comprising a step of:
measuring a width of the resist and a length from an end portion of the resist to an end portion of the aperture side of the upper portion included in the second partition, between the etching and the removing of the resist.

10. The manufacturing method of claim 7, further comprising a step of:
measuring a width of the first sealing layer adhering to the second partition and a length from an end portion of the first sealing layer adhering to the second partition to an end portion on the aperture side of the upper portion included in the second partition, after the removing of the resist.

11. The manufacturing method of claim 2, further comprising a step of:
forming a conductive layer in the panel portion and the margin area before the forming of the rib layer, wherein
the second partition is formed at a position overlapping the conductive layer in the target area in the margin area.

12. The manufacturing method of claim 11, further comprising a step of:
removing the resist after the etching, wherein
parts formed on the second partition of the first stacked film and parts adhering to the second partition of the first sealing layer remain in the target area in the margin area.

13. The manufacturing method of claim 11, further comprising a step of:
measuring a width of the resist and a length from an end portion of the resist to an end portion of the conductive layer, between the etching and the removing of the resist.

14. The manufacturing method of claim 11, further comprising a step of:
measuring a width of the first sealing layer adhering to the second partition and a length from an end portion of the first sealing layer adhering to the second partition to an end portion of the conductive layer, after the removing of the resist.

15. A mother substrate for a display device, comprising:
a plurality of panel portions each including a display area and a surrounding area around the display area;
a margin area around the plurality of panel portions;
a lower electrode provided in the display area;
a rib layer provided in the plurality of panel portions and the margin area;
a first partition provided in the display area;
a first stacked film provided in a first area included in each of the plurality of panel portions and the margin area and including an organic layer of a first color;
a first sealing layer covering the first stacked film; and
a second stacked film provided in a second area included in each of the plurality of panel portions and the margin area and including an organic layer of a second color;
a second sealing layer covering the second stacked film; and
a plurality of second partitions provided in the first area and the second area included in the margin area, wherein
each of the first partition and the second partition has a lower portion and an upper portion having an end portion protruding relative to a side surface of the lower portion,
the first stacked film is provided on the upper portion of the second partition provided in the first area,
the first sealing layer adhering to the second partition is provided around the second partition provided in the first area,
the second stacked film is provided on the upper portion of the second partition provided in the second area, and
the second sealing layer adhering to the second partition is provided around the second partition provided in the second area.

16. The mother substrate of claim 15, wherein
the second partition provided in the first area is provided at a center of the first area, and
the second partition provided in the second area is provided at a center of the second area.

17. The mother substrate of claim 15, further comprising:
a third partition including the upper portion and the lower portion and surrounding the first area and the second area.

18. The mother substrate of claim 15, further comprising:
a conductive layer provided below the rib layer, wherein
the second partition overlaps the conductive layer in plan view.

19. The mother substrate of claim 17, wherein
in each of the first partition, the second partition, and the third partition, the lower portion is provided on the rib layer.

20. The mother substrate of claim 17, wherein
the lower portions included in the first partition, the second partition, and the third partition are formed of the same material, and
the upper portions included in the first partition, the second partition, and the third partition are formed of the same material.

21. A mother substrate for a display device, comprising:
a plurality of panel portions each including a display area and a surrounding area around the display area;
a margin area around the plurality of panel portions;
a lower electrode provided in the display area;
a rib layer provided in the plurality of panel portions and the margin area;
a first partition provided in the display area;
a first stacked film provided in a first area included in each of the plurality of panel portions and the margin area and including an organic layer of a first color;
a first sealing layer covering the first stacked film;
a second stacked film provided in a second area included in each of the plurality of panel portions and the margin area and including an organic layer of a second color;
a second sealing layer covering the second stacked film; and
a plurality of second partitions provided at positions overlapping the first area and the second area included in the margin area in plan view, wherein
each of the first partition and the second partition has a lower portion and an upper portion having an end portion protruding relative to a side surface of the lower portion,
the second partition has an aperture at a center of the second partition,
the first stacked film is provided in an aperture of the second partition provided at a position overlapping the first area,
the first sealing layer adhering to the second partition is provided around the aperture of the second partition provided at the position overlapping the first area,
the second stacked film is provided in an aperture of the second partition provided at a position overlapping the second area, and
the second sealing layer adhering to the second partition is provided around the aperture of the second partition provided at the position overlapping the second area.

22. The mother substrate of claim 21, wherein
the aperture of the second partition provided in the first area is located at a center of the first area, and
the aperture of the second partition provided in the second area is located at a center of the second area.

23. The mother substrate of claim 21, wherein
the lower portion is provided on the rib layer in each of the first partition and the second partition.

24. The mother substrate of claim 21, wherein
the lower portions included in the first partition and the second partition are formed of the same material, and
the upper portions included in the first partition and the second partition are formed of the same material.
